(19) United States
(12) Patent Application Publication
(10) Pub. No.: US 2010/0051920 A1
(43) Pub. Date: Mar. 4, 2010

(54) Composite Article Including a Cation-Sensitive Layer

(75) Inventors: Dimitris Elias Katsoulis, Midland, MI (US); Elizabeth McQuiston, Midland, MI (US); Thomas D. Barnard, Murrietta, CA (US); Nathan Greer, Freeland, MI (US); Paul Schalk, Bay City, MI (US)

Correspondence Address: HOWARD & HOWARD ATTORNEYS PLLC, 450 West Fourth Street, Royal Oak, MI, 48067, US

(73) Assignee: DOW CORNING CORPORATION, Midland, MI (US)

(21) Appl. No.: 12/520,307

(22) PCT Filed: Dec. 19, 2007
(86) PCT No.: PCT/US2007/026030

§ 371 Date: Jun. 19, 2009

(30) Foreign Application Priority Data
Dec. 20, 2006 (US) 60870951

(51) Int. Cl. H01L 51/52; B32B 9/00; B32B 5/00; B32B 17/06; B32B 15/04

(52) U.S. Cl. 257/40; 428/447; 428/336; 428/429; 428/450; 428/337; 257/E51.022

(57) ABSTRACT

A composite article includes a substrate having a surface, a cation-sensitive layer including a cation-sensitive material disposed on the surface of the substrate, and a silicone layer disposed between the substrate and the cation-sensitive layer. Cations are present on the surface of the substrate in an amount of at least 0.1 atomic weight percent based on the total atomic weight of the atoms on the surface of the substrate. The silicone layer includes a cured silicone composition for preventing cations from migrating from the substrate to the cation-sensitive layer. The inclusion of the silicone layer between the cation-sensitive layer and the substrate enables the use of materials for the substrate that have not been useable in the past due to the presence of excessive amounts of cations in the materials.

### BACKGROUND OF THE INVENTION

1. Field of the Invention

The present invention generally relates to a composite article that includes a cation-sensitive layer. More specifically, the present invention relates to a composite article including the cation-sensitive layer, which may be an organic light-emitting layer, that is disposed on a substrate.

2. Description of the Prior Art

Organic light-emitting diodes (OLEDs) are well known in the art. OLEDs hold promise as a viable alternative to traditional lighting sources as well as for use in visual display and communication applications. The OLEDs typically include, in the most basic form, a substrate, an anode disposed on the substrate, a hole-injecting layer disposed on the anode, an organic light-emitting layer disposed on the hole-injecting layer, a cathode disposed on the organic light-emitting layer, and a barrier layer formed from metal, glass, or another vitreous material disposed on the cathode. At least one of the substrate and the barrier layer are formed from glass or another vitreous material to allow light emitted from the light-emitting layer to escape from the OLED. At least one of the anode and the cathode are also transparent.

One of the barriers to commercialization of OLEDs is maximizing lifetime of the OLEDs. In particular, organic light-emitting materials that form the organic light-emitting layer are sensitive to and degrade when exposed to moisture, oxygen, and other environmental contaminants. Glass has traditionally been used as the substrate. While glass exhibits excellent impermeability to moisture, oxygen, and other environmental contaminants, conventional glass has a high level of cations present therein. The cations typically leach out of the glass and localize on the surface of the glass when the glass is exposed to high temperatures and/or other environmental conditions. The cations are typically present on the surface of the glass in an amount of about 3.5 atomic weight percent based on the total atomic weight of the atoms on the surface of the glass. It has recently been found that the organic light-emitting material is especially sensitive to the cations that are present in the conventional glass, and that the sensitivity of the organic light-emitting materials to the cations accelerates degradation of luminescence of the organic light-emitting materials. Further, the cations have been found to short circuit the electric-conducting layers, such as the anode and the cathode. As such, only high quality glass having no to low levels of cations has been used for the substrate in the past. The high quality glass is very expensive, compared to conventional glass that includes high levels of cations, and also presents processing difficulties due to a higher melting point resulting from the absence of cations in the glass. As such, it would be very desirable, from a cost and production standpoint, to use conventional glass in place of the high quality glass.

Although glass functions as an excellent environmental barrier, glass substrates have yielded to polymeric substrates in many situations to enable the OLEDs to be more flexible. The polymeric substrates provide insufficient impermeability to moisture, oxygen, and other environmental contaminants. As such, additional environmental barriers must be used as set forth, for example, in U.S. Pat. No. 6,570,325 to Graff et al. Although Graff et al. discloses an environmental barrier including a decoupling layer, a barrier layer is also required in addition to the decoupling layer. This is due to the use of the decoupling layer merely to interrupt the propagation of defects from one layer to another. The barrier layer, which is formed from metals, metal oxides, or other metal-based compounds, is required to provide the environmental barrier with sufficient impermeability to moisture, oxygen, and other environmental contaminants. The anode is disposed on the environmental barrier and is sealed from the environment, along with the organic light-emitting material.

Due to the deficiencies of the prior art, there is an opportunity to provide a composite article including a cation-sensitive layer, such as an OLED, that further includes a substrate including cations on a surface thereof in an amount of at least 0.1 atomic weight percent based on the total atomic weight of the atoms on the surface of the substrate, such as conventional glass, without the attendant deficiencies that have been experienced by using such vitreous materials in the past.

### SUMMARY OF THE INVENTION AND ADVANTAGES

The present invention provides a composite article including a substrate having a surface, a cation-sensitive layer including a cation-sensitive material disposed on the surface of the substrate, and a silicone layer disposed between the substrate and the cation-sensitive layer. Cations are present on the surface of the substrate in an amount of at least 0.1 atomic weight percent based on the total atomic weight of the atoms on the surface of the substrate. The silicone layer includes a cured silicone composition for preventing cations from migrating from the substrate to the cation-sensitive layer.

The inclusion of the silicone layer between the cation-sensitive layer and the substrate enables the use of materials for the substrate that have not been useable in the past due to the presence of excessive amounts of cations in the materials. Further, the cured silicone composition may provide other features such as protection of the surface of the substrate from the formation of defects and, thus, improving the strength of the substrate. The cured silicone composition follows a morphology of the surface and serves a planarizing function as well. The composite article of the present invention may be formed through a continuous process, which is more efficient than a batch process and thereby may decrease the time and cost of making the composite articles. Finally, by including the silicone layer, the thickness of the substrate including glass or other relatively brittle materials may be minimized below thicknesses that were previously feasible due to fragility of the substrates. The presence of the silicone layer also allows the substrates of minimal thickness to bend beyond an original bending radius, which is useful in applications that require flexibility of the composite article.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a cross-sectional side view of a composite article of the present invention;

FIG. 2 is a cross-sectional side view of another embodiment of the composite article of the present invention;

FIG. 3 is a graph representing secondary ion mass spectrometry data obtained for soda-lime glass and composite articles including the soda lime glass and a silicone layer including various cured silicone compositions at various depths after curing the silicone compositions;

FIG. 4 is a graph representing secondary ion mass spectrometry data obtained for soda-lime glass and composite articles including the soda lime glass and a silicone layer including various cured silicone compositions at various depths after curing the silicone compositions and after annealing the composite articles at a temperature of about 300° C. for a period of about 60 minutes in N₂ atmosphere; and

FIG. 5 is a photograph of a composite article of the present invention.

### DETAILED DESCRIPTION OF THE INVENTION

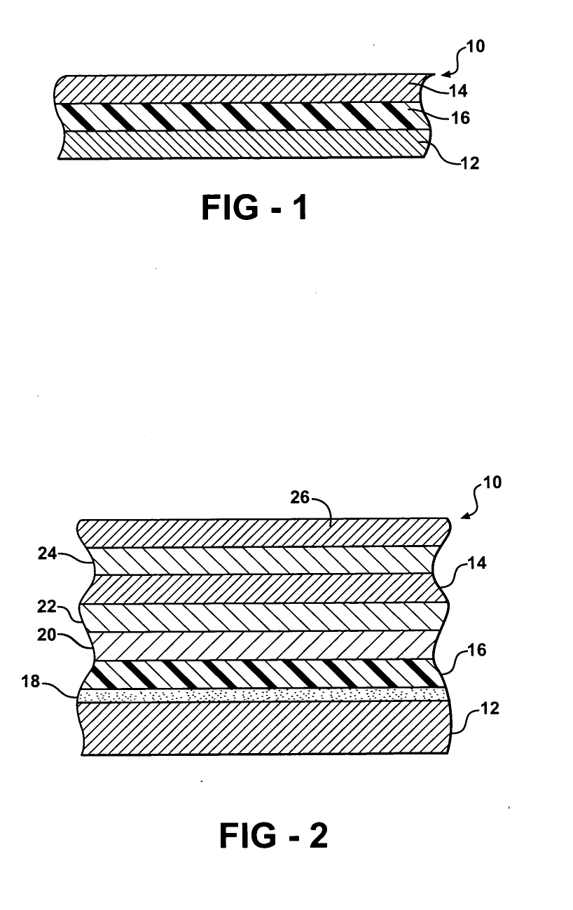

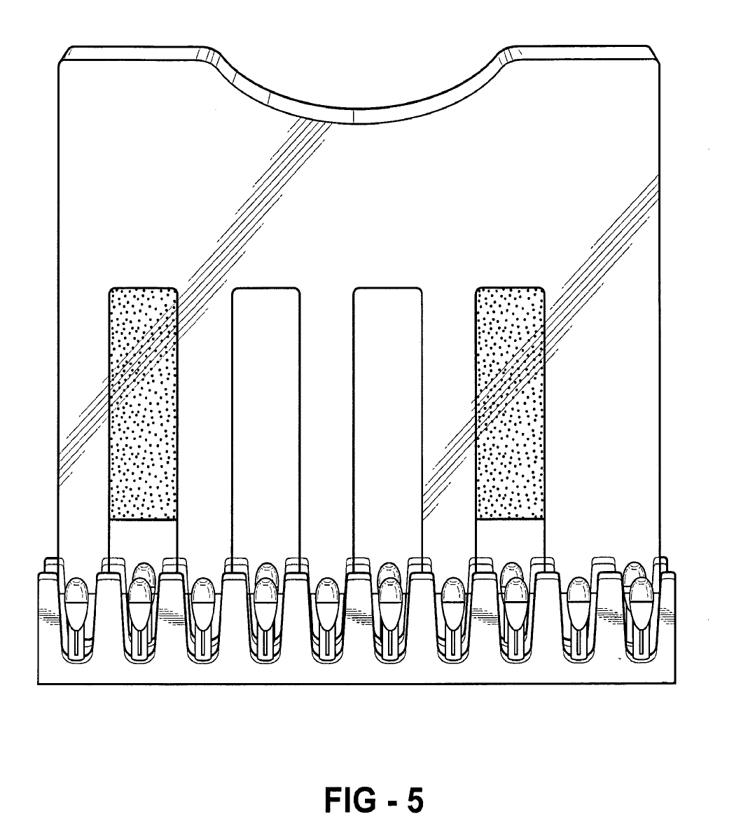

Referring to the Figures, wherein like numerals indicate corresponding parts throughout the several views, a composite article 10 is shown generally at 10 in FIG. 1. The composite article 10 includes a substrate 12 that includes cations on a surface thereof, a cation-sensitive layer 14 disposed on the substrate 12, and a silicone layer 16 disposed between the substrate 12 and the cation-sensitive layer 14. The cation-sensitive layer 14 includes a cation-sensitive material, which may be any material that experiences deterioration in performance when exposed to cations. The silicone layer 16 effectively prevents cations from migrating from the substrate 12 to the cation-sensitive layer 14, and the silicone layer 16 includes no or low levels of cations comparable to the amount of cations present in the high quality glass of the prior art. The migration of cations from the substrate 12 to the cation-sensitive layer 14 has prevented the use of substrates 12 including cations from use with cation-sensitive layers 14 in the past. The composite article 10 of the present invention is especially suitable for use as organic light-emitting diodes (OLEDs), as shown in FIG. 5, and as will be appreciated with reference to the further description of the composite article 10 below. However, it is to be appreciated that the composite article 10 may be any such article that includes the substrate 12, a cation-sensitive layer 14, and silicone layer 16 disposed therebetween.

The substrate 12 more specifically comprises a material that includes cations. A cation, as the term is used herein, is any positively charged atom or group of atoms. Common cations that are present in the substrate 12 include sodium, potassium, calcium, sulphur, tin, magnesium, and aluminum. Although the cations are present throughout the material and, thus, throughout the entire substrate 12, it is the cations on the surface of the substrate 12 that are measured since those are the cations that are prone to migrating to the cation-sensitive layer 14. The cations are typically present on the surface of the substrate 12 in an amount of at least 0.1 atomic weight percent based on the total atomic weight of the atoms on the surface of the substrate 12, and may reach an amount of about 15 atomic weight percent based on the total atomic weight of the atoms on the surface of the substrate 12, especially after annealing the substrate 12 at temperatures of from 300 to 500° C. for a period of about 60 minutes in N₂ atmosphere. In essence, the material may have cations present in amounts that were not acceptable in the past due to the effect of the cations on the cation-sensitive layer 14. Such high levels of cations are possible in the present composite articles 10 due to the presence of the silicone layer 16 in the composite article 10, which prevents the cations from migrating from the substrate 12, specifically the surface of the substrate 12, to the cation-sensitive layer 14.

The material may be selected from the group of glass, metal, and combinations thereof. The substrate 12 is typically formed from glass, which is typically both transparent and provides excellent impermeability to moisture, oxygen, and other environmental contaminants. Specific examples of suitable glass may be selected from the group of soda-lime glass, borofloat glass, aluminasilicate glass, and combinations thereof. However, the substrate 12 may also be metal, such as steel or aluminum.

The material is typically produced with no special processing to remove the cations. The special processing that has been used in the past to remove the cations is costly and imparts the material with undesirable properties, especially when the material is glass. More specifically, the melting temperature of glass that has been subjected to the processing to remove cations is typically much higher, typically 400° F. or higher, than the melting temperature of glass that has not been subjected to the processing. The higher melting temperature of the glass that has been subjected to the special processing requires higher temperatures during formation of the composite article 10 in order to shape or form the substrate 12 into a desired shape, thereby increasing the cost of production of the composite articles 10.

The thickness of the substrate 12 depends on the intended application. For example, a relatively thick substrate 12, on the order of greater than 1 millimeter, may be used for applications in which the weight or relative flexibility of the composite article 10 is immaterial. In other applications, the thickness of the substrate 12 may be less than or equal to 1 millimeter, typically less than 100 micron, which may be desirable for applications in which minimal weight and maximized flexibility of the composite article 10 is desired while maintaining the excellent impermeability that is attributable to glass. Specific examples of suitable substrates 12 that have a thickness of less than 1 millimeter are those commercially available under the trade name Microsheet® from Corning, Inc. of Corning N.Y., which has a thickness of about 75 micron. Microsheet® substrates 12 may have a thickness of as little as 0.05 mm, which is insufficiently thin and brittle for use in many applications. However, due to the presence of the silicone layer 16 of the present invention in the composite article 10, the silicone layer 16 serves to reinforce and enhance the strength of the substrate 12, making such thin substrates 12 feasible for many applications in which the substrates would not otherwise be useable.

The composite article 10 of the present invention further comprises the silicone layer 16 disposed on the substrate 12. Typically, the silicone layer 16 is operatively connected to the substrate 12. The silicone layer 16 may be operatively connected to the substrate 12 through either the presence of at least one functional group present in a silicone composition that is used to form the silicone layer 16, or may be operatively connected to the substrate 12 through an adhesive layer 18, both as described in further detail below.

The silicone layer 16 comprises a cured silicone composition, and may further comprise a fiber reinforcement. When used, the fiber reinforcement may be impregnated with the cured silicone composition, i.e., the silicone layer 16 may be a single layer including the fiber reinforcement and the cured silicone composition. However, it is to be appreciated that the fiber reinforcement is optional and may be omitted in many applications. Methods of incorporating the fiber reinforcement into the silicone layer 16 are known in the art.

In one embodiment, the cured silicone composition is further defined as a hydrosilylation-cured silicone composition. The hydrosilylation-cured silicone composition comprises the reaction product of (A) a silicone resin and (B) an organosilicon compound having an average of at least two silicon-bonded hydrogen atoms per molecule in an amount sufficient to cure the silicone resin, in the presence of (C) a catalytic amount of a hydrosilylation catalyst. Any hydrosilylation-cured silicone compositions that are known in the art may be suitable for purposes of the present invention; however, some hydrosilylation-cured silicone compositions may be more suitable than others. More specifically, some silicone resins (A) may be more suitable than others.

The silicone resin (A) typically has silicon-bonded alkenyl groups or silicon-bonded hydrogen atoms. The silicone resin (A) is typically a copolymer including R²SiO_{3/2} units, i.e., T units, and/or SiO_{4/2} units, i.e., Q units, in combination with R¹R²₂SiO_{1/2} units, i.e., M units, and/or R²₂SiO_{2/2} units, i.e., D units, wherein R¹ is a C₁ to C₁₀ hydrocarbyl group or a C₁ to C₁₀ halogen-substituted hydrocarbyl group, both free of aliphatic unsaturation, and R² is R¹, an alkenyl group, or hydrogen. For example, the silicone resin can be a DT resin, an MT resin, an MDT resin, a DTQ resin, and MTQ resin, and MDTQ resin, a DQ resin, an MQ resin, a DTQ resin, an MTQ resin, or an MDQ resin. As used herein, the term “free of aliphatic unsaturation” means the hydrocarbyl or halogen-substituted hydrocarbyl group does not contain an aliphatic carbon-carbon double bond or carbon-carbon triple bond.

The C₁ to C₁₀ hydrocarbyl group and C₁ to C₁₀ halogen-substituted hydrocarbyl group represented by R¹ more typically have from 1 to 6 carbon atoms. Acyclic hydrocarbyl and halogen-substituted hydrocarbyl groups containing at least 3 carbon atoms can have a branched or unbranched structure. Examples of hydrocarbyl groups represented by R¹ include, but are not limited to, alkyl groups, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, octyl, nonyl, and decyl; cycloalkyl groups, such as cyclopentyl, cyclohexyl, and methylcyclohexyl; aryl groups, such as phenyl and naphthyl; alkaryl groups, such as tolyl and xylyl; and aralkyl groups, such as benzyl and phenethyl. Examples of halogen-substituted hydrocarbyl groups represented by R¹ include, but are not limited to, 3,3,3-trifluoropropyl, 3-chloropropyl, chlorophenyl, dichlorophenyl, 2,2,2-trifluoroethyl, 2,2,3,3-tetrafluoropropyl, and 2,2,3,3,4,4,5,5-octafluoropentyl.

The alkenyl groups represented by R², which may be the same or different within the silicone resin, typically have from 2 to about 10 carbon atoms, alternatively from 2 to 6 carbon atoms, and are exemplified by, but not limited to, vinyl, allyl, butenyl, hexenyl, and octenyl. In one embodiment, R² is predominantly the alkenyl group. In this embodiment, typically at least 50 mol %, alternatively at least 65 mol %, alternatively at least 80 mol %, of the groups represented by R² in the silicone resin are alkenyl groups. As used herein, the mol % of alkenyl groups in R² is defined as a ratio of the number of moles of silicon-bonded alkenyl groups in the silicone resin to the total number of moles of the R² groups in the resin, multiplied by 100. In another embodiment, R² is predominantly hydrogen. In this embodiment, typically at least 50 mol %, alternatively at least 65 mol %, alternatively at least 80 mol %, of the groups represented by R² in the silicone resin are hydrogen. The mol % of hydrogen in R² is defined as a ratio of the number of moles of silicon-bonded hydrogen in the silicone resin to the total number of moles of the R² groups in the resin, multiplied by 100.

According to a first embodiment, the silicone resin (A) has the formula:

(R¹R²₂SiO_{1/2})_{w}(R²₂SiO_{2/2})ₓ(R²SiO_{3/2})_{y}(SiO_{4/2})_{z} (I)

wherein R¹ and R² are as described and exemplified above, w, x, y, and z are mole fractions. The silicone resin represented by formula (I) has an average of at least two silicon-bonded alkenyl groups per molecule. More specifically, the subscript w typically has a value of from 0 to 0.9, alternatively from 0.02 to 0.75, alternatively from 0.05 to 0.3. The subscript x typically has a value of from 0 to 0.9, alternatively from 0 to 0.45, alternatively from 0 to 0.25. The subscript y typically has a value of from 0 to 0.99, alternatively from 0.25 to 0.8, alternatively from 0.5 to 0.8. The subscript z typically has a value of from 0 to 0.85, alternatively from 0 to 0.25, alternatively from 0 to 0.15. Also, the ratio y+z/(w+x+y+z) is typically from 0.1 to 0.99, alternatively from 0.5 to 0.95, alternatively from 0.65 to 0.9. Further, the ratio w+x/(w+x+y+z) is typically from 0.01 to 0.90, alternatively from 0.05 to 0.5, alternatively from 0.1 to 0.35.

When R² is predominantly the alkenyl group, specific examples of silicone resins represented by formula (I) above include, but are not limited to, resins having the following formulae:

(Vi₂MeSiO_{1/2})_{0.25}(PhSiO_{3/2})_{0.75}, (ViMe₂SiO_{1/2})_{0.25}(PhSiO_{3/2})_{0.75},

(ViMe₂SiO_{1/2})_{0.25}(MeSiO_{3/2})_{0.25}(PhSiO_{3/2})_{0.50},

(ViMe₂SiO_{1/2})_{0.15}(PhSiO_{3/2})_{0.75}(SiO_{4/2})_{0.1}, and

(Vi₂MeSiO_{1/2})_{0.15}(ViMe₂SiO_{1/2})_{0.1}(PhSiO_{3/2})_{0.75},

wherein Me is methyl, Vi is vinyl, Ph is phenyl, and the numerical subscripts outside the parenthesis denote mole fractions corresponding to either w, x, y, or z as described above for formula (I). The sequence of units in the preceding formulae is not to be viewed in any way as limiting to the scope of the invention.

When R² is predominantly hydrogen, specific examples of silicone resins represented by formula (I) above include, but are not limited to, resins having the following formulae:

(HMe₂SiO_{1/2})_{0.25}(PhSiO_{3/2})_{0.75}, (HMeSiO_{2/2})_{0.3}(PhSiO_{3/2})_{0.6}(MeSiO_{3/2})_{0.1},

and (Me₃SiO_{1/2})_{0.1}(H₂SiO_{2/2})_{0.1}(MeSiO_{3/2})_{0.4}(PhSiO_{3/2})_{0.4},

wherein Me is methyl, Ph is phenyl, and the numerical subscripts outside the parenthesis denote mole fractions. The sequence of units in the preceding formulae is not to be viewed in any way as limiting to the scope of the invention.

The silicone resin represented by formula (I) typically has a number-average molecular weight (Mₙ) of from 500 to 50,000, alternatively from 500 to 10,000, alternatively 1,000 to 3,000, where the molecular weight is determined by gel permeation chromatography employing a low angle laser light scattering detector, or a refractive index detector and silicone resin (MQ) standards.

The viscosity of the silicone resin represented by formula (I) at 25° C. is typically from 0.01 to 100,000 Pa·s, alternatively from 0.1 to 10,000 Pa·s, alternatively from 1 to 100 Pa·s.

The silicone resin represented by formula (I) typically includes less than 10% (w/w), alternatively less than 5% (w/w), alternatively less than 2% (w/w), of silicon-bonded hydroxy groups, as determined by ²⁹Si NMR.

Methods of preparing silicone resins represented by formula (I) are well known in the art; many of these resins are commercially available. Silicone resins represented by formula (I) are typically prepared by cohydrolyzing the appropriate mixture of chlorosilane precursors in an organic solvent, such as toluene. For example, a silicone resin including R¹R²₂SiO_{1/2} units and R²SiO_{3/2} units can be prepared by cohydrolyzing a first compound having the formula R¹R²₂SiCl and a second compound having the formula R²SiCl₃ in toluene, where R¹ and R² are as defined and exemplified above, to form aqueous hydrochloric acid and the silicone resin, which is a hydrolyzate of the first and second compounds. The aqueous hydrochloric acid and the silicone resin are separated, the silicone resin is washed with water to remove residual acid, and the silicone resin is heated in the presence of a mild condensation catalyst to “body” the silicone resin to a desired viscosity, as known in the art.

If desired, the silicone resin can be further treated with a condensation catalyst in an organic solvent to reduce the content of silicon-bonded hydroxy groups. Alternatively, first or second compounds containing hydrolysable groups other than chloro, such —Br, —I, —OCH₃, —OC(O)CH₃, —N(CH₃)₂, NHCOCH₃, and —SCH₃, can be cohydrolyzed to form the silicone resin. The properties of the silicone resin depend on the types of first and second compounds, the mole ratio of first and second compounds, the degree of condensation, and the processing conditions.

The organosilicon compound (B) has an average of at least two silicon-bonded hydrogen atoms per molecule, alternatively at least three silicon-bonded hydrogen atoms per molecule. It is generally understood that cross-linking occurs when the sum of the average number of alkenyl groups per molecule in the silicone resin (A) and the average number of silicon-bonded hydrogen atoms per molecule in the organosilicon compound (B) is greater than four. Prior to curing, the organosilicon compound (B) is present in an amount sufficient to cure the silicone resin (A).

The organosilicon compound (B) may be further defined as an organohydrogensilane, an organohydrogensiloxane, or a combination thereof. The structure of the organosilicon compound (B) can be linear, branched, cyclic, or resinous. In acyclic polysilanes and polysiloxanes, the silicon-bonded hydrogen atoms can be located at terminal, pendant, or at both terminal and pendant positions. Cyclosilanes and cyclosiloxanes typically have from 3 to 12 silicon atoms, alternatively from 3 to 10 silicon atoms, alternatively from 3 to 4 silicon atoms.

The organohydrogensilane can be a monosilane, disilane, trisilane, or polysilane. When R² is predominantly the alkenyl group, specific examples of organohydrogensilanes that are suitable for purposes of the present invention include, but are not limited to, diphenylsilane, 2-chloroethylsilane, bis[(p-dimethylsilyl)phenyl]ether, 1,4-dimethyldisilylethane, 1,3,5-tris(dimethylsilyl)benzene, 1,3,5-trimethyl-1,3,5-trisilane, poly(methylsilylene)phenylene, and poly(methylsilylene)methylene. When R² is predominantly hydrogen, specific examples of organohydrogensilanes that are suitable for purposes of the present invention include, but are not limited to, silanes having the following formulae:

Vi₄Si, PhSiVi₃, MeSiVi₃, PhMeSiVi₂, Ph₂SiVi₂, and PhSi(CH₂CH═CH₂)₃,

wherein Me is methyl, Ph is phenyl, and Vi is vinyl.

The organohydrogensilane can also have the formula:

HR¹₂Si—R³—SiR₁₂H (II)

wherein R¹ is as defined and exemplified above and R³ is a hydrocarbylene group free of aliphatic unsaturation having a formula selected from the following structures:

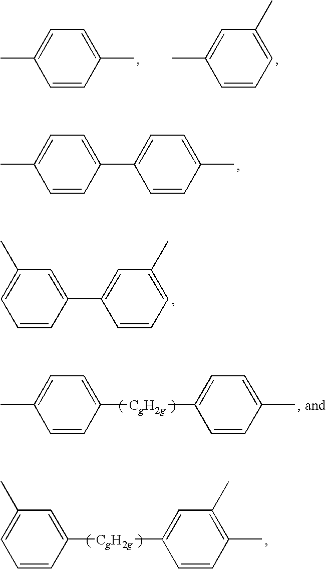

wherein g is from 1 to 6.

Specific examples of organohydrogensilanes having the formula (II), wherein R¹ and R³ are as described and exemplified above include, but are not limited to, organohydrogensilanes having a formula selected from the following structures:

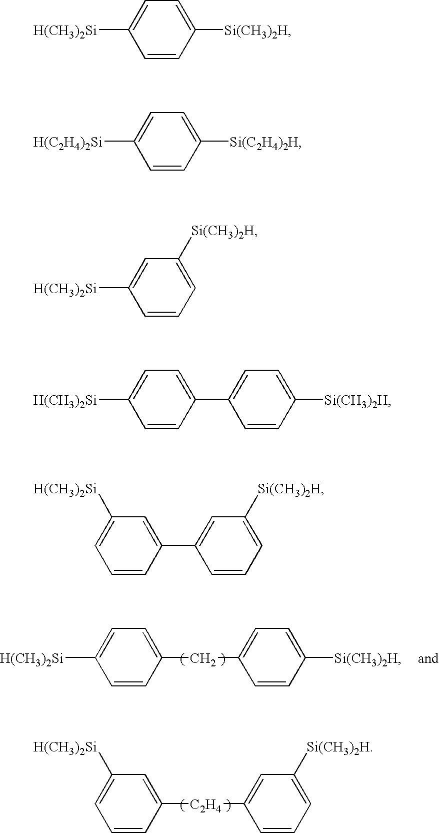

Methods of preparing the organohydrogensilanes are known in the art. For example, organohydrogensilanes can be prepared by reaction of Grignard reagents with alkyl or aryl halides. In particular, organohydrogensilanes having the formula HR¹₂Si—R³—SiR¹₂H can be prepared by treating an aryl dihalide having the formula R³X₂ with magnesium in ether to produce the corresponding Grignard reagent and then treating the Grignard reagent with a chlorosilane having the formula HR¹₂SiCl, where R¹and R³ are as described and exemplified above.

The organohydrogensiloxane can be a disiloxane, trisiloxane, or polysiloxane. Examples of organosiloxanes suitable for use as the organosilicon compound (B) when R² is predominantly hydrogen include, but are not limited to, siloxanes having the following formulae:

PhSi(OSiMe₂H)₃, Si(OSiMe₂H)₄, MeSi(OSiMe₂H)₃, and Ph₂Si(OSiMe₂H)₂,

wherein Me is methyl, and Ph is phenyl.

Specific examples of organohydrogensiloxanes that are suitable for purposes of the present invention when R² is predominantly alkenyl group including, but are not limited to, 1,1,3,3-tetramethyldisiloxane, 1,1,3,3-tetraphenyldisiloxane, phenyltris(dimethylsiloxy)silane, 1,3,5-trimethylcyclotrisiloxane, a trimethylsiloxy-terminated poly(methylhydrogensiloxane), a trimethylsiloxy-terminated poly(dimethylsiloxane/methylhydrogensiloxane), a dimethylhydrogensiloxy-terminated poly(methylhydrogensiloxane), and a resin including HMe₂SiO_{1/2} units, Me₃SiO_{1/2} units, and SiO_{4/2} units, wherein Me is methyl.

The organohydrogensiloxane can also be an organohydrogenpolysiloxane resin. The organohydrogenpolysiloxane resin is typically a copolymer including R⁴SiO_{3/2} units, i.e., T units, and/or SiO_{4/2} units, i.e., Q units, in combination with R¹R⁴₂SiO_{1/2} units, i.e., M units, and/or R⁴₂SiO_{2/2} units, i.e., D units, wherein R¹ is as described and exemplified above. For example, the organohydrogenpolysiloxane resin can be a DT resin, an MT resin, an MDT resin, a DTQ resin, and MTQ resin, and MDTQ resin, a DQ resin, an MQ resin, a DTQ resin, an MTQ resin, or an MDQ resin.

The group represented by R⁴ is either R¹ or an organosilylalkyl group having at least one silicon-bonded hydrogen atom. Examples of organosilylalkyl groups represented by R⁴ include, but are not limited to, groups having a formula selected from the following structures:

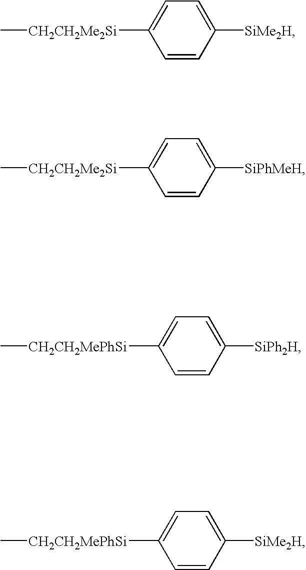

—CH₂CH₂SiMe₂H, —CH—₂CH₂SiMe₂CₙH₂ₙSiMe₂H, —CH₂CH₂SiMe₂CₙH₂ₙSiMePhH, —CH₂CH₂SiMePhH, —CH₂CH₂SiPh₂H, —CH₂CH₂SiMePhCₙH₂ₙSiPh₂H, —CH₂CH₂SiMePhCₙH₂ₙSiMe₂H, —CH₂CH₂SiMePhOSiMePhH, and —CH₂CH₂SiMePhOSiPh(OSiMePhH)₂, wherein Me is methyl, Ph is phenyl, and the subscript n has a value of from 2 to 10. Typically, at least 50 mol %, alternatively at least 65 mol %, alternatively at least 80 mol % of the groups represented by R⁴ in the organohydrogenpolysiloxane resin are organosilylalkyl groups having at least one silicon-bonded hydrogen atom. As used herein, the mol % of organosilylalkyl groups in R⁴ is defined as a ratio of the number of moles of silicon-bonded organosilylalkyl groups in the silicone resin to the total number of moles of the R⁴ groups in the resin, multiplied by 100.

The organohydrogenpolysiloxane resin typically has the formula:

(R¹R⁴₂SiO_{1/2})_{w}(R⁴₂SiO_{2/2})ₓ(R⁴SiO_{3/2})_{y}(SiO_{4/2})_{z} (III)

wherein R¹, R⁴, w, x, y, and z are each as defined and exemplified above.

Specific examples of organohydrogenpolysiloxane resins represent by formula (III) above include, but are not limited to, resins having the following formulae:

((HMe₂SiC₆H₄SiMe₂CH₂CH₂)₂MeSiO_{1/2})_{0.12}(PhSiO_{3/2})_{0.88},

((HMe₂SiC₆H₄SiMe₂CH₂CH₂)₂MeSiO_{1/2})_{0.17}(PhSiO_{3/2})_{0.83},

((HMe₂SiC₆H₄SiMe₂CH₂CH₂)₂MeSiO_{1/2})_{0.17}(MeSiO_{3/2})_{0.17}(PhSiO_{3/2})_{0.66},

((HMe₂SiC₆H₄SiMe₂CH₂CH₂)₂MeSiO_{1/2})_{0.15}(PhSiO_{3/2})_{0.75}(SiO_{4/2})_{0.10}, and

((HMe₂SiC₆H₄SiMe₂CH₂CH₂)₂MeSiO_{1/2})_{0.08}((HMe₂SiC₆H₄SiMe₂CH₂CH₂)

Me₂SiO_{1/2})_{0.06}(PhSiO_{3/2})_{0.86},

wherein Me is methyl, Ph is phenyl, C₆H₄ denotes a para-phenylene group, and the numerical subscripts outside the parenthesis denote mole fractions. The sequence of units in the preceding formulae is not to be viewed in any way as limiting to the scope of the invention.

Specific examples of organohydrogenpolysiloxane resins include, but are not limited to, resins having the following formulae:

((HMe₂SiC₆H₄SiMe₂CH₂CH₂)₂MeSiO_{1/2})_{0.12}(PhSiO_{3/2})_{0.88},

(HMe₂SiC₆H₄SiMe₂CH₂CH₂)₂MeSiO_{1/2})_{0.17}(PhSiO_{3/2})_{0.83},

((HMe₂SiC₆H₄SiMe₂CH₂CH₂)₂MeSiO_{1/2})_{0.17}(MeSiO_{3/2})_{0.17}(PhSiO_{3/2})_{0.66},

((HMe₂SiC₆H₄SiMe₂CH₂CH₂)₂MeSiO_{1/2})_{0.15}(PhSiO_{3/2})_{0.75}(SiO_{4/2})_{0.10}, and

((HMe₂SiC₆H₄SiMe₂CH₂CH₂)₂MeSiO_{1/2})_{0.08}((HMe₂SiC₆H₄SiMe₂CH₂CH₂)

Me₂SiO_{1/2})_{0.06} (PhSiO_{3/2})_{0.86}, where Me is methyl, Ph is phenyl, C₆H₄ denotes a para-phenylene group, and the numerical subscripts outside the parenthesis denote mole fractions. The sequence of units in the preceding formulae is not to be viewed in any way as limiting to the scope of the invention.

The organohydrogenpolysiloxane resin having the formula (III) can be prepared by reacting a reaction mixture including (a) a silicone resin having the formula (R¹R²₂SiO_{1/2})_{w}(R²₂SiO_{2/2})ₓ(R²SiO_{3/2})_{y}(SiO_{4/2})_{z} represented by formula (I) above and an organosilicon compound (b) having an average of from two to four silicon-bonded hydrogen atoms per molecule and a molecular weight less than 1,000, in the presence of (c) a hydrosilylation catalyst and, optionally, (d) an organic solvent, wherein R¹, R², w, x, y, and z are each as defined and exemplified above, provided the silicone resin (a) has an average of at least two silicon-bonded alkenyl groups per molecule, and the mole ratio of silicon-bonded hydrogen atoms in (b) to alkenyl groups in (a) is from 1.5 to 5. Silicone resin (a) can be the same as or different than the specific silicone resin used as component (A) to form the hydrosilylation-cured silicone composition.

As set forth above, organosilicon compound (b) has an average of from two to four silicon-bonded hydrogen atoms per molecule. Alternatively, the organosilicon compound (b) has an average of from two to three silicon-bonded hydrogen atoms per molecule. As also set forth above, the organosilicon compound (b) typically has a molecular weight less than 1,000, alternatively less than 750, alternatively less than 500. The organosilicon compound (b) further includes silicon-bonded organic groups that may be selected from the group of hydrocarbyl groups and halogen-substituted hydrocarbyl groups, both free of aliphatic unsaturation, which are as described and exemplified above for R¹.

Organosilicon compound (b) can be an organohydrogensilane or an organohydrogensiloxane, each of which are defined and exemplified in detail above. Organosilicon compound (b) can further be a single organosilicon compound or a mixture comprising two or more different organosilicon compounds, each as described above. For example, organosilicon compound (B) can be a single organohydrogensilane, a mixture of two different organohydrogensilanes, a single organohydrogensiloxane, a mixture of two different organohydrogensiloxanes, or a mixture of an organohydrogensilane and an organohydrogensiloxane. The mole ratio of silicon-bonded hydrogen atoms in organosilicon compound (b) to alkenyl groups in silicone resin (a) is typically from 1.5 to 5, alternatively from 1.75 to 3, alternatively from 2 to 2.5.

Hydrosilylation catalyst (c) can be any of the well-known hydrosilylation catalysts comprising a platinum group metal (i.e., platinum, rhodium, ruthenium, palladium, osmium and iridium) or a compound containing a platinum group metal. Preferably, the platinum group metal is platinum, based on its high activity in hydrosilylation reactions.

Specific hydrosilylation catalysts suitable for (c) include the complexes of chloroplatinic acid and certain vinyl-containing organosiloxanes disclosed by Willing in U.S. Pat. No. 3,419,593, which is hereby incorporated by reference. A catalyst of this type is the reaction product of chloroplatinic acid and 1,3-diethenyl-1,1,3,3-tetramethyldisiloxane.

The hydrosilylation catalyst can also be a supported hydrosilylation catalyst comprising a solid support having a platinum group metal on the surface thereof. A supported catalyst can be conveniently separated from the organohydrogenpolysiloxane resin represented by formula (III), for example, by filtering the reaction mixture. Examples of supported catalysts include, but are not limited to, platinum on carbon, palladium on carbon, ruthenium on carbon, rhodium on carbon, platinum on silica, palladium on silica, platinum on alumina, palladium on alumina, and ruthenium on alumina.

The concentration of hydrosilylation catalyst (c) is sufficient to catalyze the addition reaction of silicone resin (a) with organosilicon compound (b). Typically, the concentration of hydrosilylation catalyst (c) is sufficient to provide from 0.1 to 1000 ppm of a platinum group metal, alternatively from 1 to 500 ppm of a platinum group metal, alternatively from 5 to 150 ppm of a platinum group metal, based on the combined weight of silicone resin (a) and organosilicon compound (b). The rate of reaction is very slow below 0.1 ppm of platinum group metal. The use of more than 1000 ppm of platinum group metal results in no appreciable increase in reaction rate, and is therefore uneconomical.

Organic solvent (d) is at least one organic solvent. The organic solvent (d) can be any aprotic or dipolar aprotic organic solvent that does not react with silicone resin (a), organosilicon compound (b), or the resulting organohydrogenpolysiloxane resin under the conditions of the present method, and is miscible with components (a), (b), and the organohydrogenpolysiloxane resin.

Examples of organic solvents (d) that are suitable for purposes of the present invention include, but are not limited to, saturated aliphatic hydrocarbons such as n-pentane, hexane, n-heptane, isooctane and dodecane; cycloaliphatic hydrocarbons such as cyclopentane and cyclohexane; aromatic hydrocarbons such as benzene, toluene, xylene and mesitylene; cyclic ethers such as tetrahydrofuran (THF) and dioxane; ketones such as methyl isobutyl ketone (MIBK); halogenated alkanes such as trichloroethane; and halogenated aromatic hydrocarbons such as bromobenzene and chlorobenzene. Organic solvent (d) can be a single organic solvent or a mixture comprising two or more different organic solvents, each as described above. The concentration of organic solvent (d) is typically from 0 to 99% (w/w), alternatively from 30 to 80% (w/w), alternatively from 45 to 60% (w/w), based on the total weight of the reaction mixture.

The reaction to form the organohydrogenpolysiloxane resin represented by formula (III) can be carried out in any standard reactor suitable for hydrosilylation reactions. Suitable reactors include glass and Teflon-lined glass reactors. Preferably, the reactor is equipped with a means of agitation, such as stirring. Also, preferably, the reaction is carried out in an inert atmosphere, such as nitrogen or argon, in the absence of moisture.

The silicone resin (a), organosilicon compound (b), hydrosilylation catalyst (c), and, optionally, organic solvent (d), can be combined in any order. Typically, organosilicon compound (b) and hydrosilylation catalyst (c) are combined before the introduction of the silicone resin (a) and, optionally, organic solvent (d). The reaction is typically carried out at a temperature of from 0 to 150° C., alternatively from room temperature (˜23±2° C.) to 115° C. When the temperature is less than 0° C., the rate of reaction is typically very slow. The reaction time depends on several factors, such as the structures of the silicone resin (a) and the organosilicon compound (b), and the temperature. The time of reaction is typically from 1 to 24 h at a temperature of from room temperature (˜23±2° C.) to 150° C. The optimum reaction time can be determined by routine experimentation. It is to be appreciated that, during formation of the silicone layer on the substrate, the silicone composition is typically applied to the substrate using various known methods, after which the reaction is carried out as set forth above.

The organohydrogenpolysiloxane resin represented by formula (III) can be used without isolation or purification or the organohydrogenpolysiloxane resin can be separated from most of the organic solvent (d) by conventional methods of evaporation. For example, the reaction mixture can be heated under reduced pressure. Moreover, when the hydrosilylation catalyst (c) is a supported catalyst, as described above, the organohydrogenpolysiloxane resin can be readily separated from the hydrosilylation catalyst (c) by filtering the reaction mixture. However, the hydrosilylation catalyst may remain mixed with the organohydrogenpolysiloxane resin and be used as hydrosilylation catalyst (C).

The organosilicon compound (B) can be a single organosilicon compound or a mixture comprising two or more different organosilicon compounds, each as described above. For example, the organosilicon compound (B) can be a single organohydrogensilane, a mixture of two different organohydrogensilanes, a single organohydrogensiloxane, a mixture of two different organohydrogensiloxanes, or a mixture of an organohydrogensilane and an organohydrogensiloxane. In particular, the organosilicon compound (B) can be a mixture comprising the organohydrogenpolysiloxane resin having the formula (III) in an amount of at least 0.5% (w/w), alternatively at least 50% (w/w), alternatively at least 75% (w/w), based on the total weight of the organosilicon compound (B), with the organosilicon compound (B) further comprising an organohydrogensilane and/or organohydrogensiloxane, the latter different from the organohydrogenpolysiloxane resin.

The concentration of organosilicon compound (B) is sufficient to cure (cross-link) the silicone resin (A). The exact amount of organosilicon compound (B) depends on the desired extent of cure. The concentration of organosilicon compound (B) is typically sufficient to provide from 0.4 to 2 moles of silicon-bonded hydrogen atoms, alternatively from 0.8 to 1.5 moles of silicon-bonded hydrogen atoms, alternatively from 0.9 to 1.1 moles of silicon-bonded hydrogen atoms, per mole of alkenyl groups in silicone resin (A).

Hydrosilylation catalyst (C) includes at least one hydrosilylation catalyst that promotes the reaction between silicone resin (A) and organosilicon compound (B). In one embodiment, the hydrosilylation catalyst (C) may be the same as the hydrosilylation catalyst (c) described above for producing the organohydrogenpolysiloxane resin. In addition, the hydrosilylation catalyst (C) can also be a microencapsulated platinum group metal-containing catalyst comprising a platinum group metal encapsulated in a thermoplastic resin. Microencapsulated hydrosilylation catalysts and methods of preparing them are well known in the art, as exemplified in U.S. Pat. No. 4,766,176 and the references cited therein, and U.S. Pat. No. 5,017,654. The hydrosilylation catalyst (C) can be a single catalyst or a mixture comprising two or more different catalysts that differ in at least one property, such as structure, form, platinum group metal, complexing ligand, and thermoplastic resin.

In another embodiment, the hydrosilylation catalyst (C) may be at least one photoactivated hydrosilylation catalyst. The photoactivated hydrosilylation catalyst can be any hydrosilylation catalyst capable of catalyzing the hydrosilylation of the silicone resin (A) and the organosilicon compound (B) upon exposure to radiation having a wavelength of from 150 to 800 nm. The photoactivated hydrosilylation catalyst can be any of the well-known hydrosilylation catalysts comprising a platinum group metal or a compound containing a platinum group metal. The platinum group metals include platinum, rhodium, ruthenium, palladium, osmium and iridium. Typically, the platinum group metal is platinum, based on its high activity in hydrosilylation reactions. The suitability of particular photoactivated hydrosilylation catalyst for use in the silicone composition of the present invention can be readily determined by routine experimentation.

Specific examples of photoactivated hydrosilylation catalysts suitable for purposes of the present invention include, but are not limited to, platinum(II) β-diketonate complexes such as platinum(II) bis(2,4-pentanedioate), platinum(II) bis(2,4-hexanedioate), platinum(II) bis(2,4-heptanedioate), platinum(II) bis(1-phenyl-1,3-butanedioate, platinum(II) bis(1,3-diphenyl-1,3-propanedioate), platinum(II) bis(1,1,1,5,5,5-hexafluoro-2,4-pentanedioate); (η-cyclopentadienyl)trialkylplatinum complexes, such as (Cp)trimethylplatinum, (Cp)ethyldimethylplatinum, (Cp)triethylplatinum, (chloro-Cp)trimethylplatinum, and (trimethylsilyl-Cp)trimethylplatinum, where Cp represents cyclopentadienyl; triazene oxide-transition metal complexes, such as Pt[C₆H₅NNNOCH₃]₄, Pt[p-CN—C₆H₄NNNOC₆H₁₁]₄, Pt[p-H₃COC₆H₄NNNOC₆H₁₁]₄, Pt[p-CH₃(CH₂)ₓ—C₆H₄NNNOCH₃]₄, 1,5-cyclooctadiene.Pt[p-CN—C₆H₄NNNOC₆H₁₁]₂, 1,5-cyclooctadiene.Pt[p-CH₃O—C₆H₄NNNOCH₃]₂, [(C₆H₅)₃P]₃Rh[p-CN—C₆H₄NNNOC₆H₁₁], and Pd[p-CH₃(CH₂)ₓ—C₆H₄NNNOCH₃]₂, where x is 1, 3, 5, 11, or 17; (η-diolefin)(σ-aryl)platinum complexes, such as (η⁴-1,5-cyclooctadienyl)diphenylplatinum, η⁴-1,3,5,7-cyclooctatetraenyl)diphenylplatinum, (η⁴-2,5-norboradienyl)diphenylplatinum, (η⁴-1,5-cyclooctadienyl)bis-(4-dimethylaminophenyl)platinum, (η⁴-1,5-cyclooctadienyl)bis-(4-acetylphenyl)platinum, and (η⁴-1,5-cyclooctadienyl)bis-(4-trifluormethylphenyl)platinum. Preferably, the photoactivated hydrosilylation catalyst is a Pt(II) β-diketonate complex and more preferably the catalyst is platinum(II) bis(2,4-pentanedioate). The hydrosilylation catalyst (C) can be a single photoactivated hydrosilylation catalyst or a mixture comprising two or more different photoactivated hydrosilylation catalysts.

Methods of preparing photoactivated hydrosilylation catalysts are well known in the art. For example, methods of preparing platinum(II) β-diketonates are reported by Guo et al. (Chemistry of Materials, 1998, 10, 531-536). Methods of preparing (η-cyclopentadienyl)-trialkylplatinum complexes and are disclosed in U.S. Pat. No. 4,510,094. Methods of preparing triazene oxide-transition metal complexes are disclosed in U.S. Pat. No. 5,496,961. And, methods of preparing (η-diolefin)(σ-aryl)platinum complexes are taught in U.S. Pat. No. 4,530,879.

The concentration of the hydrosilylation catalyst (C) is sufficient to catalyze the addition reaction of the silicone resin (A) and the organosilicon compound (B). The concentration of the hydrosilylation catalyst (C) is sufficient to provide typically from 0.1 to 1000 ppm of platinum group metal, alternatively from 0.5 to 100 ppm of platinum group metal, alternatively from 1 to 25 ppm of platinum group metal, based on the combined weight of the silicone resin (A) and the organosilicon compound (B).

Optionally, the hydrosilylation-cured silicone composition further includes (D) a silicone rubber having a formula selected from the group of:

R¹R²₂SiO(R²₂SiO)ₐSiR²₂R¹; and (i)

R⁵R¹₂SiO(R₁R⁵SiO)_{b}SiR¹₂R⁵; (ii)

wherein R¹ and R² are as defined and exemplified above, R⁵ is R¹ or —H, subscripts a and b each have a value of from 1 to 4, from 2 to 4 or from 2 to 3, and w, x, y, and z are also as defined and exemplified above, provided the silicone resin and the silicone rubber (D)(i) each have an average of at least two silicon-bonded alkenyl groups per molecule, the silicone rubber (D)(ii) has an average of at least two silicon-bonded hydrogen atoms per molecule, and the mole ratio of silicon-bonded alkenyl groups or silicon-bonded hydrogen atoms in the silicone rubber (D) to silicon-bonded alkenyl groups in the silicone resin (A) is from 0.01 to 0.5.

Specific examples of silicone rubbers suitable for use as component (D)(i) include, but are not limited to, silicone rubbers having the following formulae:

ViMe₂SiO(Me₂SiO)ₐSiMe₂Vi, ViMe₂SiO(Ph₂SiO)ₐSiMe₂Vi, and

ViMe₂SiO(PhMeSiO)ₐSiMe₂Vi,

wherein Me is methyl, Ph is phenyl, Vi is vinyl, and the subscript a has a value of from 1 to 4. Silicone rubber (D)(i) can be a single silicone rubber or a mixture comprising two or more different silicone rubbers that each satisfy the formula for (D)(i).

Specific examples of silicone rubbers suitable for use as silicone rubber (D)(ii) include, but are not limited to, silicone rubbers having the following formulae:

HMe₂SiO(Me₂SiO)_{b}SiMe₂H, HMe₂SiO(Ph₂SiO)_{b}SiMe₂H, HMe₂SiO(PhMeSiO)_{b}SiMe₂H, and HMe₂SiO(Ph₂SiO)₂(Me₂SiO)₂SiMe₂H,

wherein Me is methyl, Ph is phenyl, and the subscript b has a value of from 1 to 4. Component (D)(ii) can be a single silicone rubber or a mixture comprising two or more different silicone rubbers that each satisfy the formula for (D)(ii).

The mole ratio of silicon-bonded alkenyl groups or silicon-bonded hydrogen atoms in the silicone rubber (D) to silicon-bonded alkenyl groups in the silicone resin (A) is typically from 0.01 to 0.5, alternatively from 0.05 to 0.4, alternatively from 0.1 to 0.3.

When the silicone rubber (D) is (D)(i), the concentration of the organosilicon compound (B) is such that the ratio of the number of moles of silicon-bonded hydrogen atoms in the organosilicon compound (B) to the sum of the number of moles of silicon-bonded alkenyl groups in the silicone resin (A) and the silicone rubber (D)(i) is typically from 0.4 to 2, alternatively from 0.8 to 1.5, alternatively from 0.9 to 1.1. Furthermore, when the silicone rubber (D) is (D)(ii), the concentration of the organosilicon compound (B) is such that the ratio of the sum of the number of moles of silicon-bonded hydrogen atoms in the organosilicon compound (B) and the silicone rubber (D)(ii) to the number of moles of silicon-bonded alkenyl groups in the silicone resin (A) is typically from 0.4 to 2, alternatively from 0.8 to 1.5, alternatively from 0.9 to 1.1.

Methods of preparing silicone rubbers containing silicon-bonded alkenyl groups or silicon-bonded hydrogen atoms are well known in the art; many of these compounds are commercially available.

In another embodiment of the present invention, the hydrosilylation-cured silicone composition comprises the reaction product of (A′) a rubber-modified silicone resin and the organosilicon compound (B), in the presence of (C) the catalytic amount of the hydrosilylation catalyst. The rubber-modified silicone resin (A′) may be prepared by reacting the silicone resin (A) and a silicone rubber (D)(iii) having the following formulae:

R⁵R¹₂SiO(R¹R⁵SiO)_{c}SiR¹₂R⁵, R¹R²₂SiO(R²₂SiO)_{d}SiR²₂R¹ ,

wherein R¹ and R⁵ are as defined and exemplified above and c and d each have a value of from 4 to 1000, alternatively from 10 to 500, alternatively from 10 to 50, in the presence of the hydrosilylation catalyst (c) and, optionally, an organic solvent, provided the silicone resin (A) has an average of at least two silicon-bonded alkenyl groups per molecule, the silicone rubber (D)(iii) has an average of at least two silicon-bonded hydrogen atoms per molecule, and the mole ratio of silicon-bonded hydrogen atoms in the silicone rubber (D)(iii) to silicon-bonded alkenyl groups in silicone resin (A) is from 0.01 to 0.5. When organic solvent is present, the rubber-modified silicone resin (A′) is miscible in the organic solvent and does not form a precipitate or suspension.

The silicone resin (A), silicone rubber (D)(iii), hydrosilylation catalyst (c), and organic solvent can be combined in any order. Typically, the silicone resin (A), silicone rubber (D)(iii), and organic solvent are combined before the introduction of the hydrosilylation catalyst (c).

The reaction is typically carried out at a temperature of from room temperature (˜23±2° C.) to 150° C., alternatively from room temperature to 100° C. The reaction time depends on several factors, including the structures of the silicone resin (A) and the silicone rubber (D)(iii) and the temperature. The components are typically allowed to react for a period of time sufficient to complete the hydrosilylation reaction. This means the components are typically allowed to react until at least 95 mol %, alternatively at least 98 mol %, alternatively at least 99 mol %, of the silicon-bonded hydrogen atoms originally present in the silicone rubber (D)(iii) have been consumed in the hydrosilylation reaction, as determined by FTIR spectrometry. The time of reaction is typically from 0.5 to 24 h at a temperature of from room temperature (˜23±2° C.) to 100° C. The optimum reaction time can be determined by routine experimentation. It is to be appreciated that, during formation of the silicone layer on the substrate, the silicone composition is typically applied to the substrate using various known methods, after which the reaction is carried out as set forth above.

The mole ratio of silicon-bonded hydrogen atoms in the silicone rubber (D)(iii) to silicon-bonded alkenyl groups in the silicone resin (A) is typically from 0.01 to 0.5, alternatively from 0.05 to 0.4, alternatively from 0.1 to 0.3.

The concentration of the hydrosilylation catalyst (c) is sufficient to catalyze the addition reaction of the silicone resin (A) with the silicone rubber (D)(iii). Typically, the concentration of the hydrosilylation catalyst (c) is sufficient to provide from 0.1 to 1000 ppm of a platinum group metal, based on the combined weight of the resin and the rubber.

The concentration of the organic solvent is typically from 0 to 95% (w/w), alternatively from 10 to 75% (w/w), alternatively from 40 to 60% (w/w), based on the total weight of the reaction mixture.

The rubber-modified silicone resin (A′) can be used without isolation or purification or the rubber-modified silicone resin (A′) can be separated from most of the solvent by conventional methods of evaporation. For example, the reaction mixture can be heated under reduced pressure. Moreover, when the hydrosilylation catalyst (c) is a supported catalyst, described above, the rubber-modified silicone resin (A′) can be readily separated from the hydrosilylation catalyst (c) by filtering the reaction mixture. However, when the rubber-modified silicone resin (A′) is not separated from the hydrosilylation catalyst (c) used to prepare the rubber-modified silicone resin (A′), the hydrosilylation catalyst (c) may be used as the hydrosilylation catalyst (C).

The hydrosilylation-cured silicone composition of the present invention can comprise additional ingredients, as known in the art. Examples of additional ingredients include, but are not limited to, hydrosilylation catalyst inhibitors, such as 3-methyl-3-penten-1-yne, 3,5-dimethyl-3-hexen-1-yne, 3,5-dimethyl-1-hexyn-3-ol, 1-ethynyl-1-cyclohexanol, 2-phenyl-3-butyn-2-ol, vinylcyclosiloxanes, and triphenylphosphine; adhesion promoters, such as the adhesion promoters taught in U.S. Pat. Nos. 4,087,585 and 5,194,649; anti-oxidants; heat stabilizers; UV stabilizers; flow control additives; and diluents, such as organic solvents and reactive diluents. The inhibitors are especially useful in the silicone compositions during formation of the silicone layer on the substrate. The inhibitors allow curing of the silicone composition to be controlled after the resin, organosilicon compound, and catalyst are mixed together. The inhibitors allow sufficient working time to be able to apply the silicone composition onto the substrate prior to gelling and, ultimately, curing of the silicone composition.

As an alternative to the hydrosilylation-cured silicone composition, condensation-cured silicone compositions are also suitable for the silicone composition of the present invention.

The condensation-cured silicone composition typically includes the reaction product of a silicone resin (A″) having silicon-bonded hydroxy or hydrolysable groups and, optionally, a cross-linking agent (B′) having silicon-bonded hydrolysable groups, and optionally a condensation catalyst (C′). The silicone resin (A″) is typically a copolymer containing T and/or Q siloxane units in combination with M and/or D siloxane units.

The condensation-cured silicone composition may be any condensation-cured silicone composition as known in the art. However, certain condensation-cured silicone compositions may be particularly suitable for purposes of the present invention. According to one embodiment, the silicone resin (A″) has the formula:

(R¹R⁶₂SiO_{1/2})_{w}(R⁶₂SiO_{2/2})ₓ(R⁶SiO_{3/2})_{y′}(SiO_{4/2})_{z′} (IV)

wherein R¹ is as defined and exemplified above, R⁶ is R¹, —H, —OH, or a hydrolysable group, and w′ is from 0 to 0.8, preferably from 0.02 to 0.75, and more preferably from 0.05 to 0.3, x′ is from 0 to 0.95, preferably from 0.05 to 0.8, and more preferably from 0.1 to 0.3, y′ is from 0 to 1, preferably from 0.25 to 0.8, and more preferably from 0.5 to 0.8, and z′ is from 0 to 0.99, preferably from 0.2 to 0.8, and more preferably from 0.4 to 0.6, and the silicone resin (A″) has an average of at least two silicon-bonded hydrogen atoms, hydroxy groups, or hydrolysable groups per molecule. As used herein the term “hydrolysable group” means the silicon-bonded group reacts with water in the absence of a catalyst at any temperature from room temperature (˜23±2° C/) to 100° C. within several minutes, for example thirty minutes, to form a silanol (Si—OH) group. Examples of hydrolysable groups represented by R⁶ include, but are not limited to, —Cl, —Br, —OR⁷, —OCH₂CH₂OR⁷, CH₃C(═O)O—, Et(Me)C═N—O—, CH₃C(═O)N(CH₃)—, and —ONH₂, wherein R⁷ is C₁ to C₈ hydrocarbyl or C₁ to C₈ halogen-substituted hydrocarbyl.

The hydrocarbyl and halogen-substituted hydrocarbyl groups represented by R⁷ typically have from 1 to 8 carbon atoms, alternatively from 3 to 6 carbon atoms. Acyclic hydrocarbyl and halogen-substituted hydrocarbyl groups containing at least 3 carbon atoms can have a branched or unbranched structure. Examples of hydrocarbyl groups represented by R⁷ include, but are not limited to, unbranched and branched alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, and octyl; cycloalkyl, such as cyclopentyl, cyclohexyl, and methylcyclohexyl; phenyl; alkaryl, such as tolyl and xylyl; aralkyl, such as benzyl and phenethyl; alkenyl, such as vinyl, allyl, and propenyl; arylalkenyl, such as styryl; and alkynyl, such as ethynyl and propynyl. Examples of halogen-substituted hydrocarbyl groups represented by R⁷ include, but are not limited to, 3,3,3-trifluoropropyl, 3-chloropropyl, chlorophenyl, and dichlorophenyl.

Typically, at least 5 mol %, alternatively at least 15 mol %, alternatively at least 30 mol % of the groups R⁶ in the silicone resin are hydrogen, hydroxy, or a hydrolysable group. As used herein, the mol % of groups in R⁶ is defined as a ratio of the number of moles of silicon-bonded groups in the silicone resin (A″) to the total number of moles of the R⁶ groups in the silicone resin (A″), multiplied by 100.

Specific examples of cured silicone resins formed from silicone resin (A″) include, but are not limited to, cured silicone resins having the following formulae:

(MeSiO_{3/2})ₙ, (PhSiO_{3/2})ₙ, (Me₃SiO_{1/2})_{0.8}(SiO_{4/2})_{0.2},

(MeSiO_{3/2})_{0.67}(PhSiO_{3/2})_{0.33},

(MeSiO_{3/2})_{0.45}(PhSiO_{3/2})_{0.40}(Ph₂SiO_{2/2})_{0.1}(PhMeSiO_{2/2})_{0.05},

(PhSiO_{3/2})_{0.4}(MeSiO_{3/2})_{0.45}(PhSiO_{3/2})_{0.1}(PhMeSiO_{2/2})_{0.05}, and

(PhSiO_{3/2})_{0.4}(MeSiO_{3/2})_{0.1}(PhMeSiO_{2/2})_{0.5},

wherein Me is methyl, Ph is phenyl, the numerical subscripts outside the parenthesis denote mole fractions, and the subscript n has a value such that the silicone resin has a number-average molecular weight of from 500 to 50,000. The sequence of units in the preceding formulae is not to be viewed in any way as limiting to the scope of the invention.

As set forth above, the silicone resin (A″) represented by formula (IV) typically has a number-average molecular weight (Mₙ ) of from 500 to 50,000. Alternatively, the silicone resin (A″) may have a Mₙ of at least 300, alternatively 1,000 to 3,000, where the molecular weight is determined by gel permeation chromatography employing a low angle laser light scattering detector, or a refractive index detector and silicone resin (MQ) standards.

The viscosity of the silicone resin (A″) at 25° C. is typically from 0.01 Pa·s to solid, alternatively from 0.1 to 100,000 Pa·s, alternatively from 1 to 1,000 Pa s.

Methods of preparing silicone resins (A″) represented by formula (IV) are well known in the art; many of these resins are commercially available. Silicone resins (A″) represented by formula (IV) are typically prepared by cohydrolyzing the appropriate mixture of chlorosilane precursors in an organic solvent, such as toluene. For example, a silicone resin including R¹ R⁶₂SiO_{1/2} units and R⁶SiO_{3/2} units can be prepared by cohydrolyzing a first compound having the formula R¹R⁶₂SiCl and a second compound having the formula R⁶SiCl₃ in toluene, where R¹ and R⁶ are as defined and exemplified above. The cohydrolyzing process is described above in terms of the hydrosilylation-cured silicone composition. The cohydrolyzed reactants can be further “bodied” to a desired extent to control the amount of crosslinkable groups and viscosity.

The Q units in formula (IV) can be in the form of discrete particles in the silicone resin (A″). The particle size is typically from 1 nm to 20 μm. Examples of these particles include, but not limited to, silica (SiO_{4/2}) particles of 15 nm in diameter.

The condensation cured silicone composition can further contain inorganic fillers such as silica, alumina, calcium carbonate, and mica. Depending upon the intended use for the composite article, the filler may preferably have a particle size that is below the wavelength of visible light. In addition, when the filler is used, appropriate measures are preferably taken to prevent agglomeration of the particles during application of the silicone composition to the substrate or during curing of the silicone composition.

In another embodiment, the condensation-cured silicone composition comprises the reaction product of a rubber-modified silicone resin (A′″) and the other optional components. The rubber-modified silicone resin (A′″) may be prepared by reacting an organosilicon compound selected from (i) a silicone resin having the formula (R¹R⁶₂SiO_{1/2})_{w}(R⁶₂SiO_{2/2})ₓ(R⁶SiO_{3/2})_{y}(SiO_{4/2})_{z} and (ii) hydrolysable precursors of (i), and (iii) a silicone rubber having the formula R⁸₃SiO(R¹R⁸SiO)ₘSiR⁸₃ in the presence of water, (iv) a condensation catalyst, and (v) an organic solvent, wherein R¹ and R⁶ are as defined and exemplified above, R⁸ is R¹ or a hydrolysable group, m is from 2 to 1,000, alternatively from 4 to 500, alternatively from 8 to 400, and w, x, y, and z are as defined and exemplified above, and silicone resin (i) has an average of at least two silicon-bonded hydroxy or hydrolysable groups per molecule, the silicone rubber (iii) has an average of at least two silicon-bonded hydrolysable groups per molecule, and the mole ratio of silicon-bonded hydrolysable groups in the silicone rubber (iii) to silicon-bonded hydroxy or hydrolysable groups in the silicone resin (i) is from 0.01 to 1.5, alternatively from 0.05 to 0.8, alternatively from 0.2 to 0.5.

Typically at least 5 mol %, alternatively at least 15 mol %, alternatively at least 30 mol % of the groups R⁶ in the silicone resin (i) are hydroxy or hydrolysable groups.

The silicone resin (i) typically has a number-average molecular weight (Mₙ ) of at least 300, alternatively from 500 to 10,000, alternatively 1,000 to 3,000, where the molecular weight is determined by gel permeation chromatography employing a low angle laser light scattering detector, or a refractive index detector and silicone resin (MQ) standards.

Specific examples of cured silicone resins formed from silicone resin (i) include, but are not limited to, cured silicone resins having the following formulae:

(MeSiO_{3/2})ₙ, (PhSiO_{3/2})ₙ,

(PhSiO_{3/2})_{0.4}(MeSiO_{3/2})_{0.45}(PhSiO_{3/2})_{0.1}(PhMeSiO_{2/2})_{0.05}, and

(PhSiO_{3/2})_{0.3}(SiO_{4/2})_{0.1}(Me₂SiO_{2/2})_{0.2}(Ph₂SiO_{2/2})_{0.4}, where Me is methyl, Ph is phenyl, the numerical subscripts outside the parenthesis denote mole fractions, and the subscript n has a value such that the silicone resin has a number-average molecular weight of from 500 to 50,000. The sequence of units in the preceding formulae is not to be viewed in any way as limiting to the scope of the invention. Silicone resin (i) can be a single silicone resin or a mixture comprising two or more different silicone resins, each having the specified formula.

As used herein, the term “hydrolysable precursors” refers to silanes having hydrolysable groups that are suitable for use as starting materials (precursors) for preparation of the silicone resin (i). The hydrolysable precursors (ii) can be represented by the formulae R¹R⁸₂SiX, R⁸₂SiX₂, R⁸SiX₃, and SiX₄, wherein R¹, R⁸, and X are as defined and exemplified above.

Specific examples of hydrolysable precursors (ii) include, but are not limited to, silanes having the formulae:

Me₂ViSiCl, Me₃SiCl, MeSi(OEt)₃, PhSiCl₃, MeSiCl₃, Me₂SiCl₂, PhMeSiCl₂, SiCl₄, Ph₂SiCl₂, PhSi(OMe)₃, MeSi(OMe)₃, PhMeSi(OMe)₂, and Si(OEt)₄,

wherein Me is methyl, Et is ethyl, and Ph is phenyl.

Specific examples of silicone rubbers (iii) include, but are not limited to, silicone rubbers having the following formulae:

(EtO)₃SiO(Me₂SiO)₅₅Si(OEt)₃, (EtO)₃SiO(Me₂SiO)₁₆Si(OEt)₃,

(EtO)₃SiO(Me₂SiO)₃₈₆Si(OEt)₃, and (EtO)₂MeSiO(PhMeSiO)₁₀SiMe(OEt)₂,

wherein Me is methyl and Et is ethyl.

The reaction is typically carried out at a temperature of from room temperature (˜23±2° C.) to 180° C., alternatively from room temperature to 100° C.

The reaction time depends on several factors, including the structures of the silicone resin (i) and the silicone rubber (iii), and the temperature. The components are typically allowed to react for a period of time sufficient to complete the condensation reaction. This means the components are allowed to react until at least 95 mol %, alternatively at least 98 mol %, alternatively at least 99 mol %, of the silicon-bonded hydrolysable groups originally present in the silicone rubber (iii) have been consumed in the condensation reaction, as determined by ²⁹Si NMR spectrometry. The time of reaction is typically from 1 to 30 h at a temperature of from room temperature (˜23±2° C.) to 100° C. The optimum reaction time can be determined by routine experimentation. It is to be appreciated that, during formation of the silicone layer on the substrate, the silicone composition is typically applied to the substrate using various known methods, after which the reaction is carried out as set forth above.

Suitable condensation catalysts (iv) are described in further detail below, and suitable organic solvents (v) are described above in the context of rubber-modified silicone resin (A′) above. The concentration of the condensation catalyst (iv) is sufficient to catalyze the condensation reaction of the silicone resin (i) with the silicone rubber (iii). Typically, the concentration of the condensation catalyst (iv) is from 0.01 to 2% (w/w), alternatively from 0.01 to 1% (w/w), alternatively from 0.05 to 0.2% (w/w), based on the weight of the silicon resin (i). The concentration of the organic solvent (v) is typically from 10 to 95% (w/w), alternatively from 20 to 85% (w/w), alternatively from 50 to 80% (w/w), based on the total weight of the reaction mixture.

The concentration of water in the reaction mixture depends on the nature of the groups R⁸ in the organosilicon compound and the nature of the silicon-bonded hydrolysable groups in the silicone rubber. When the silicone resin (i) contains hydrolysable groups, the concentration of water is sufficient to effect hydrolysis of the hydrolysable groups in the silicon resin (i) and the silicone rubber (iii). For example, the concentration of water is typically from 0.01 to 3 moles, alternatively from 0.05 to 1 moles, per mole of hydrolysable group in the silicone resin (i) and the silicone rubber (iii) combined. When the silicone resin (i) does not contain hydrolysable groups, only a trace amount, e.g., 100 ppm, of water is required in the reaction mixture. Trace amounts of water are normally present in the reactants and/or solvent.

As set forth above, the condensation-cured silicone composition can further comprise the reaction product of the cross-linking agent (B′). The cross-linking agent (B′) can have the formula R⁷_{q}SiX_{4-q}, wherein R⁷ is C₁ to C₈ hydrocarbyl or C₁ to C₈ halogen-substituted hydrocarbyl, X is a hydrolysable group, and q is 0 or 1. The hydrocarbyl and halogen-substituted hydrocarbyl groups represented by R⁷, and the hydrolysable groups represented by X are as described and exemplified above.

Specific examples of cross-linking agents (B′) include, but are not limited to, alkoxy silanes such as MeSi(OCH₃)₃, CH₃Si(OCH₂CH₃)₃, CH₃Si(OCH₂CH₂CH₃)₃, CH₃Si[O(CH₂)₃CH₃]₃, CH₃CH₂Si(OCH₂CH₃)₃, C₆H₅Si(OCH₃)₃, C₆H₅CH₂Si(OCH₃)₃, C₆H₅Si(OCH₂CH₃)₃, CH₂═CHSi(OCH₃)₃, CH₂═CHCH₂Si(OCH₃)₃, CF₃CH₂CH₂Si(OCH₃)₃, CH₃ Si(OCH₂CH₂OCH₃)₃, CF₃CH₂CH₂Si(OCH₂CH₂OCH₃)₃, CH₂═CHSi(OCH₂CH₂OCH₃)₃, CH₂═CHCH₂Si(OCH₂CH₂OCH₃)₃, C₆H₅Si(OCH₂CH₂OCH₃)₃, Si(OCH₃)₄, Si(OC₂H₅)₄, and Si(OC₃H₇)₄; organoacetoxysilanes such as CH₃Si(OCOCH₃)₃, CH₃CH₂Si(OCOCH₃)₃, and CH₂═CHSi(OCOCH₃)₃; organoiminooxysilanes such as CH₃Si[O—N═C(CH₃)CH₂CH₃]₃, Si[O—N═C(CH₃)CH₂CH₃]₄, and CH₂═CHSi[O—N═C(CH₃)CH₂CH₃]₃; organoacetamidosilanes such as CH₃Si[NHC(═O)CH₃]₃ and C₆H₅Si[NHC(═O)CH₃]₃; amino silanes such as CH₃Si[NH(s-C₄H₉)]₃ and CH₃ Si(NHC₆H₁₁)₃; and organoaminooxysilanes.

The cross-linking agent (B′) can be a single silane or a mixture of two or more different silanes, each as described above. Also, methods of preparing tri- and tetra-functional silanes are well known in the art; many of these silanes are commercially available.

When used, the concentration of the cross-linking agent (B′) prior toformation of the condensation-cured silicone composition is sufficient to cure (cross-link) the condensation-cured silicone resin. The exact amount of the cross-linking agent (B′) depends on the desired extent of cure, which generally increases as the ratio of the number of moles of silicon-bonded hydrolysable groups in the cross-linking agent (B′) to the number of moles of silicon-bonded hydrogen atoms, hydroxy groups, or hydrolysable groups in the silicone resin (A″) increases. Typically, the concentration of the cross-linking agent (B′) is sufficient to provide from 0.2 to 4 moles of silicon-bonded hydrolysable groups per mole of silicon-bonded hydrogen atoms, hydroxy groups, or hydrolysable groups in the silicone resin (A″). The optimum amount of the cross-linking agent (B′) can be readily determined by routine experimentation.

Condensation catalyst (C′) can be any condensation catalyst typically used to promote condensation of silicon-bonded hydroxy (silanol) groups to form Si—O—Si linkages. Examples of condensation catalysts include, but are not limited to, amines; and complexes of lead, tin, zinc, and iron with carboxylic acids. In particular, the condensation catalyst (C′) can be selected from tin(II) and tin(IV) compounds such as tin dilaurate, tin dioctoate, and tetrabutyl tin; and titanium compounds such as titanium tetrabutoxide.

When present, the concentration of the condensation catalyst (C′) is typically from 0.1 to 10% (w/w), alternatively from 0.5 to 5% (w/w), alternatively from 1 to 3% (w/w), based on the total weight of the silicone resin (A″).

When the condensation-cured silicone composition is formed in the presence of the condensation catalyst (C′), the condensation-cured silicone composition is typically formed from a two-part composition where the silicone resin (A″) and condensation catalyst (C′) are in separate parts. To form the silicone layer, the silicone resin and the catalyst are preferably blended together to form the silicone composition, with the silicone composition then applied to the substrate and cured under conditions similar to those set forth above for curing the other condensation-cured silicone compositions.

The condensation-cured silicone composition of the present invention can comprise additional ingredients, as known in the art and as described above for the hydrosilylation-cured silicone composition.

In yet another embodiment, the silicone composition may be a free radical-cured silicone composition. Examples of free radical-cured silicone compositions include peroxide-cured silicone compositions, radiation-cured silicone compositions containing a free radical photoinitiator, and high energy radiation-cured silicone compositions. Typically, the free radical-cured silicone composition comprises the reaction product of a silicone resin (A′″) and, optionally, a cross-linking agent (B″) and/or a free radical initiator (C″) (e.g., a free radical photoinitiator or organic peroxide).

The silicone resin (A′″) can be any silicone resin that can be cured (i.e., cross-linked) by at least one method selected from (i) exposing the silicone resin to radiation having a wavelength of from 150 to 800 nm in the presence of a free radical photoinitiator, (ii) heating the silicone resin (A′″) in the presence of an organic peroxide, and (iii) exposing the silicone resin (A′″) to an electron beam. The silicone resin (A′″) is typically a copolymer containing T siloxane units and/or Q siloxane units in combination with M and/or D siloxane units.

For example, the silicone resin (A′″) may have the formula:

(R¹R⁹₂SiO_{1/2})_{w″}(R⁹₂SiO_{2/2})_{x″}(R⁹SiO_{3/2})_{y″}(SiO_{4/2})_{z″},

wherein R¹ is as defined and exemplified above, R⁹ is R¹, alkenyl, or alkynyl, w″ is from 0 to 0.99, x″ is from 0 to 0.99, y″ is from 0 to 0.99, and z″ is from 0 to 0.85, and w″+x″+y″+z″=1.

The alkenyl groups represented by R⁹, which may be the same or different, are as defined and exemplified in the description of R² above.

The alkynyl groups represented by R⁹, which may be the same or different, typically have from 2 to about 10 carbon atoms, alternatively from 2 to 6 carbon atoms, and are exemplified by, but not limited to, ethynyl, propynyl, butynyl, hexynyl, and octynyl.

The silicone resin (A′″) typically has a number-average molecular weight (Mₙ ) of at least 300, alternatively from 500 to 10,000, alternatively 1,000 to 3,000, where the molecular weight is determined by gel permeation chromatography employing a refractive index detector and silicone resin (MQ) standards.

The silicone resin (A′″) can contain less than 10% (w/w), alternatively less than 5% (w/w), alternatively less than 2% (w/w), of silicon-bonded hydroxy groups, as determined by ²⁹Si NMR.

Specific examples of silicone resins (A′″) that are suitable for purposes of the present invention include, but are not limited to, silicone resins having the following formulae:

(Vi₂MeSiO_{1/2})_{0.25}(PhSiO_{3/2})_{0.75}, (ViMe₂SiO_{1/2})_{0.25}(PhSiO_{3/2})_{0.75},

(ViMe₂SiO_{1/2})_{0.25}(MeSiO_{3/2})_{0.25}(PhSiO_{3/2})_{0.50},

(ViMe₂SiO_{1/2})_{0.15}(PhSiO_{3/2})_{0.75} (SiO_{4/2})_{0.1}, and

(Vi₂MeSiO_{1/2})0.15(ViMe₂SiO_{1/2})0.1(PhSiO_{3/2})_{0.75},

wherein Me is methyl, Vi is vinyl, Ph is phenyl, and the numerical subscripts outside the parenthesis denote mole fractions. The sequence of units in the preceding formulae is not to be viewed in any way as limiting to the scope of the invention.

The free radical-cured silicone composition of the present method can comprise additional ingredients including, but not limited to, silicone rubbers; unsaturated compounds; free radical initiators; organic solvents; UV stabilizers; sensitizers; antioxidants; fillers, such as reinforcing fillers, extending fillers, and conductive fillers; and adhesion promoters. As set forth above, when fillers are used, the fillers preferably have a particle size that is below the wavelength of visible light, and appropriate measures are preferably taken to prevent agglomeration of the particles.

The free radical-cured silicone composition can further comprise the reaction product of an unsaturated compound selected from (i) at least one organosilicon compound having at least one silicon-bonded alkenyl group per molecule, (ii) at least one organic compound having at least one aliphatic carbon-carbon double bond per molecule, and (iii) mixtures comprising (i) and (ii), wherein the unsaturated compound has a molecular weight less than 500. Alternatively, the unsaturated compound has a molecular weight less than 400 or less than 300. Also, the unsaturated compound can have a linear, branched, or cyclic structure.

The organosilicon compound (i) can be an organosilane or an organosiloxane. The organosilane can be a monosilane, disilane, trisilane, or polysilane. Similarly, the organosiloxane can be a disiloxane, trisiloxane, or polysiloxane. Cyclosilanes and cyclosiloxanes typically have from 3 to 12 silicon atoms, alternatively from 3 to 10 silicon atoms, alternatively from 3 to 4 silicon atoms. In acyclic polysilanes and polysiloxanes, the silicon-bonded alkenyl group(s) can be located at terminal, pendant, or at both terminal and pendant positions.

Specific examples of organosilanes include, but are not limited to, silanes having the following formulae:

Vi₄Si, PhSiVi₃, MeSiVi₃, PhMeSiVi₂, Ph₂SiVi₂, and PhSi(CH₂CH═CH₂)₃,

wherein Me is methyl, Ph is phenyl, and Vi is vinyl.

Specific examples of organosiloxanes include, but are not limited to, siloxanes having the following formulae:

PhSi(OSiMe₂Vi)₃, Si(OSiMe₂Vi)₄, MeSi(OSiMe₂Vi)₃, and Ph₂Si(OSiMe₂Vi)₂,

wherein Me is methyl, Vi is vinyl, and Ph is phenyl.

The organic compound can be any organic compound containing at least one aliphatic carbon-carbon double bond per molecule, provided the compound does not prevent the silicone resin (A′″) from curing to form a silicone resin film. The organic compound can be an alkene, a diene, a triene, or a polyene. Further, in acyclic organic compounds, the carbon-carbon double bond(s) can be located at terminal, pendant, or at both terminal and pendant positions.

The organic compound can contain one or more functional groups other than the aliphatic carbon-carbon double bond. Examples of suitable functional groups include, but are not limited to, —O—, >C═O, —CHO, —CO₂—, —C≡N, —NO₂, >C═C<, —C≡C—, —F, —Cl, —Br, and —I. The suitability of a particular unsaturated organic compound for use in the free-radical cured silicone composition of the present invention can be readily determined by routine experimentation.

The organic compound can have a liquid or solid state at room temperature. Also, the organic compound can be soluble, partially soluble, or insoluble in the free-radical cured silicone composition prior to curing. The normal boiling point of the organic compound, which depends on the molecular weight, structure, and number and nature of functional groups in the compound, can vary over a wide range. Preferably, the organic compound has a normal boiling point greater than the cure temperature of the composition. Otherwise, appreciable amounts of the organic compound may be removed by volatilization during cure.

Examples of organic compounds containing aliphatic carbon-carbon double bonds include, but are not limited to, 1,4-divinylbenzene, 1,3-hexadienylbenzene, and 1,2-diethenylcyclobutane.

The unsaturated compound can be a single unsaturated compound or a mixture comprising two or more different unsaturated compounds, each as described above. For example, the unsaturated compound can be a single organosilane, a mixture of two different organosilanes, a single organosiloxane, a mixture of two different organosiloxanes, a mixture of an organosilane and an organosiloxane, a single organic compound, a mixture of two different organic compounds, a mixture of an organosilane and an organic compound, or a mixture of an organosiloxane and an organic compound.

The concentration of the unsaturated compound is typically from 0 to 70% (w/w), alternatively from 10 to 50% (w/w), alternatively from 20 to 40% (w/w), based on the total weight of the free radical-cured silicone composition prior to curing.

Methods of preparing organosilanes and organosiloxanes containing silicon-bonded alkenyl groups, and organic compounds containing aliphatic carbon-carbon double bonds are well known in the art; many of these compounds are commercially available.

The free radical initiator is typically a free radical photoinitiator or an organic peroxide. Further, the free radical photoinitiator can be any free radical photoinitiator capable of initiating cure (cross-linking) of the silicone resin upon exposure to radiation having a wavelength of from 200 to 800 nm.

Examples of free radical photoinitiators include, but are not limited to, benzophenone; 4,4′-bis(dimethylamino)benzophenone; halogenated benzophenones; acetophenone; α-hydroxyacetophenone; chloro acetophenones, such as dichloroacetophenones and trichloroacetophenones; dialkoxyacetophenones, such as 2,2-diethoxyacetophenone; α-hydoxyalkylphenones, such as 2-hydroxy-2-methyl-1-phenyl-1-propanone and 1-hydroxycyclohexyl phenyl ketone; α-aminoalkylphenones, such as 2-methyl-4′-(methylthio)-2-morpholiniopropiophenone; benzoin; benzoin ethers, such as benzoin methyl ether, benzoin ethyl ether, and benzoin isobutyl ether; benzil ketals, such as 2,2-dimethoxy-2-phenylacetophenone; acylphosphinoxides, such as diphenyl(2,4,6-trimethylbenzoyl)phosphine oxide; xanthone derivatives; thioxanthone derivatives; fluorenone derivatives; methyl phenyl glyoxylate; acetonaphthone; anthraquinone derivatives; sufonyl chlorides of aromatic compounds; and O-acyl α-oximinoketones, such as 1-phenyl-1,2-propanedione-2-(O-ethoxycarbonyl)oxime.

The free radical photoinitiator can also be a polysilane, such as the phenylmethylpolysilanes defined by West in U.S. Pat. No. 4,260,780, the disclosure of which as it relates to the phenylmethylpolysilanes is hereby incorporated by reference; the aminated methylpolysilanes defined by Baney et al. in U.S. Pat. No. 4,314,956, the disclosure of which is hereby incorporated by reference as it relates to aminated methylpolysilanes; the methylpolysilanes of Peterson et al. in U.S. Pat. No. 4,276,424, the disclosure of which is hereby incorporated by reference as it relates to methylpolysilanes; and the polysilastyrene defined by West et al. in U.S. Pat. No. 4,324,901, the disclosure of which is hereby incorporated by reference as it relates to polysilastyrene.

The free radical photoinitiator can be a single free radical photoinitiator or a mixture comprising two or more different free radical photoinitiators. The concentration of the free radical photoinitiator is typically from 0.1 to 6% (w/w), alternatively from 1 to 3% (w/w), based on the weight of the silicone resin (A″″).

The free radical initiator can also be an organic peroxide. Examples of organic peroxides include, diaroyl peroxides such as dibenzoyl peroxide, di-p-chlorobenzoyl peroxide, and bis-2,4-dichlorobenzoyl peroxide; dialkyl peroxides such as di-t-butyl peroxide and 2,5-dimethyl-2,5-di-(t-butylperoxy)hexane; diaralkyl peroxides such as dicumyl peroxide; alkyl aralkyl peroxides such as t-butyl cumyl peroxide and 1,4-bis(t-butylperoxyisopropyl)benzene; and alkyl aroyl peroxides such as t-butyl perbenzoate, t-butyl peracetate, and t-butyl peroctoate.

The organic peroxide can be a single peroxide or a mixture comprising two or more different organic peroxides. The concentration of the organic peroxide is typically from 0.1 to 5% (w/w), alternatively from 0.2 to 2% (w/w), based on the weight of the silicone resin (A′″).

The free radical-cured silicone composition can further be formed in the presence of at least one organic solvent. The organic solvent can be any aprotic or dipolar aprotic organic solvent that does not react with the silicone resin (A′″) or additional ingredient(s) and is miscible with the silicone resin (A′″). Examples of organic solvents include, but are not limited to, saturated aliphatic hydrocarbons such as n-pentane, hexane, n-heptane, isooctane and dodecane; cycloaliphatic hydrocarbons such as cyclopentane and cyclohexane; aromatic hydrocarbons such as benzene, toluene, xylene and mesitylene; cyclic ethers such as tetrahydrofuran (THF) and dioxane; ketones such as methyl isobutyl ketone (MIBK); halogenated alkanes such as trichloroethane; and halogenated aromatic hydrocarbons such as bromobenzene and chlorobenzene. The organic solvent can be a single organic solvent or a mixture comprising two or more different organic solvents, each as described above.

The concentration of the organic solvent is typically from 0 to 99% (w/w), alternatively from 30 to 80% (w/w), alternatively from 45 to 60% (w/w), based on the total weight of the free radical-cured silicone composition prior to curing.

When the free-radical cured silicone composition described above is formed from one or more additional ingredients, for example, a free radical initiator, the free-radical cured silicone composition may be formed from a one-part composition comprising the silicone resin and optional ingredient(s) in a single part, or a multi-part composition comprising the components in two or more parts.

The silicone layer 16 may be formed through batch or continuous processes. For example, the silicone composition may be applied to the substrate 12 through a continuous process, such as through spin coating, dipping, spraying, or brushing, after which the silicone composition is cured to form the silicone layer 16 including the cured silicone composition. To form the cured silicone composition, the silicone composition can be heated at atmospheric, sub-atmospheric, or supra-atmospheric pressure. The silicone composition is typically heated at a temperature of from room temperature (˜23±2° C.) to 250° C., alternatively from room temperature to 200° C., alternatively from room temperature to 150° C., at atmospheric pressure. The silicone composition is heated for a length of time sufficient to cure (cross-link) the silicone composition. For example, the silicone composition is typically heated at a temperature of from 150 to 200° C. for a time of from 0.1 to 3 hours.

Alternatively, the silicone composition can be heated in a vacuum at a temperature of from 100 to 200° C. and a pressure of from 1,000 to 20,000 Pa for a time of from 0.5 to 3 hours to form the silicone layer 16. The silicone composition can be heated in the vacuum using a conventional vacuum bagging process. In a typical process, a bleeder (e.g., polyester) is applied over the silicone composition on the substrate 12, a breather (e.g., nylon, polyester) is applied over the bleeder, a vacuum bagging film (e.g., nylon) equipped with a vacuum nozzle is applied over the breather, the assembly is sealed with tape, a vacuum (e.g., 1,000 Pa) is applied to the sealed assembly, and the evacuated bag is heated as described above.

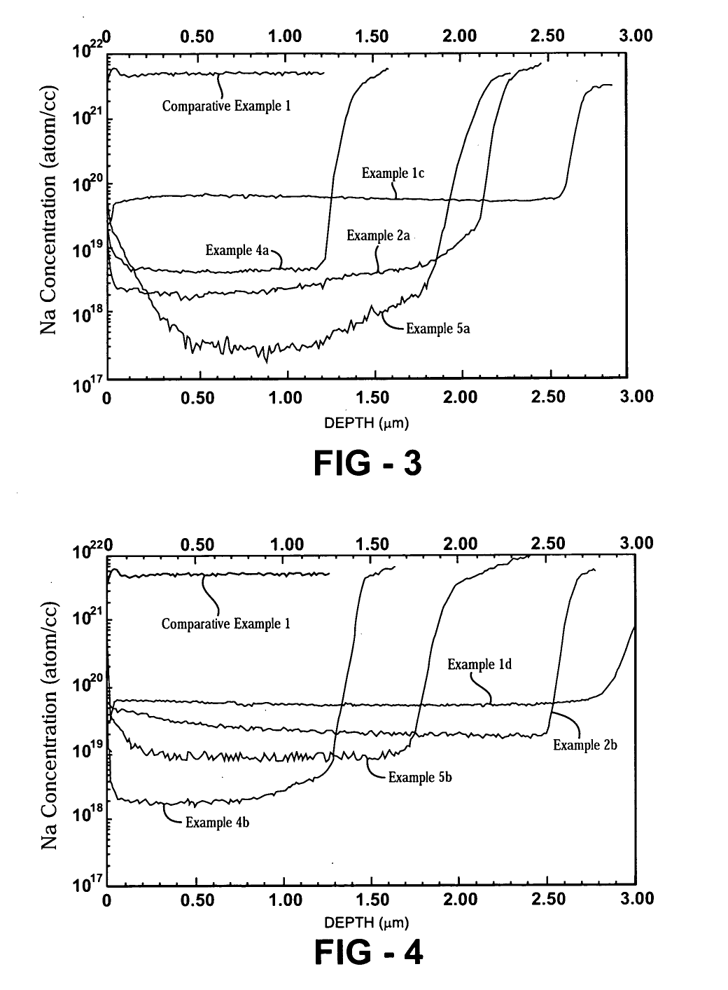

The thickness of the silicone layer 16 is dependent upon the intended application for the composite article 10. Typically, the silicone layer 16 has a thickness of at least about 0.1 micron, more typically from 0.50 to 10 micron, most typically from 1 to 3 micron. The silicone layer 16 having the thickness of at least about 0.1 micron is effective to prevent the cations from migrating from the substrate 12 to the cation-sensitive layer 14. More specifically, referring to FIGS. 3 and 4, secondary ion mass spectrography (SIMS) results are shown, which indicate the amount of sodium cations present on or near various tested surfaces as a representative measurement of the number of cations present on or near the tested surface. SIMS is very sensitive to mobile cations, down to the ppm level, and is capable of depth profiling for ions to a depth of up to 3 micron. The SIMS results are indicative of a relative number of cations present on or near the tested surface, i.e., within 3 micron of the tested surface. It is apparent, with reference to FIGS. 3 and 4, that substantially less cations are present on or near the surface of the silicone layers 16 disposed upon the substrate 12, shown at Examples 1c, 1d, 2a, 2b, 4a, 4b, 5a, and 5b, as opposed to the amount of cations present on the surface of the substrate 12, shown at Comparative Example 1 in both FIGS. 3 and 4. More specifically, less than 10²⁰ sodium cations are present at or near the surface for each of the silicone layers 16 to a depth of at least 1 micron, while the substrate 12 includes in excess of 10²¹ sodium cations present at all depths. FIG. 3 shows results when the substrate 12 and silicone layers 16 are not subjected to annealing, and FIG. 4 shows results when the substrate 12 and silicone layers 16 are subjected to annealing at a temperature of about 300° C. for a period of about 60 minutes in N₂ atmosphere.

As set forth above, the silicone layer 16 is disposed adjacent the substrate 12. More specifically, the silicone layer 16 is adhered to the substrate 12. In one embodiment, as shown in FIG. 1, the silicone layer 16 may be formed directly upon the substrate 12. The silicone layer 16 may be spin coated on the substrate 12 and subsequently cured. In this embodiment, the cured silicone composition may include at least one functional group prior to curing for adhering the cured silicone composition, and thus the silicone layer 16, to the substrate 12. The at least one functional group may be selected from the group of, but is not limited to silanol groups, alkoxy groups, epoxy groups, silicon hydride groups, acetoxy groups, and combinations thereof. To form the silicone layer 16 directly upon the substrate 12, the silicone composition may simply be applied to the substrate 12 in liquid form, after which the silicone composition may be cured.

In another embodiment, as shown in FIG. 2, the composite article 10 further includes an adhesive layer 18 disposed between the silicone layer 16 and the substrate 12. More specifically, the silicone layer 16 may be adhered to the substrate 12 with the adhesive layer 18. When used, the adhesive layer 18 typically comprises a silicone-based adhesive; however, it is to be appreciated that any adhesive suitable for adhering silicone to glass is suitable for purposes of the present invention. The silicone-based adhesive typically includes at least one functional group for adhering the adhesive layer 18 to the silicone layer 16, and also for adhering the adhesive layer 18 to the substrate 12. The at least one functional group may be selected from the group of, but is not limited to, silanol groups, alkoxy groups, epoxy groups, silicon hydride groups, acetoxy groups, and combinations thereof. Such silicone-based adhesives are known in the art. The silicone-based adhesive may be a one part or a multi-part system.

As set forth above, the composite article 10 includes the cation-sensitive layer 14. The cation-sensitive layer 14 is formed from a cation-sensitive material. The cation-sensitive material is typically an organic light-emitting material such as an oligomer or a polymer; however, the cation-sensitive material may be any type of material that is known in the art to be sensitive to cations. By “sensitive”, it is meant that cations adversely affect the performance of one or more of the functions meant for the material. For example, luminescence of the organic light-emitting material is degraded by the cations, which results in failure of the OLEDs to emit light over time. As another example, the cation-sensitive layer 14 may be an electric-conducting layer, such as circuitry or electrodes. Cations have been known to short circuit the electric-conducting layers.

The cation-sensitive layer 14 may be operatively connected to the silicone layer, as shown in FIG. 1. Alternatively, as shown in FIG. 2, the composite article 10 further includes a first electrode 20, such as an anode, disposed between the silicone layer 16 and the cation-sensitive layer 14. This is especially the case when the composite article 10 is the OLED. The first electrode 20 may be formed from any material known in the art as being suitable for electrodes, such as metals, metal oxides, and combinations thereof. Preferably, the first electrode 20 is formed from a transparent metal oxide such as, for example, indium tin oxide (ITO). However, it is to be appreciated that other transparent metal oxides may also be suitable as known in the art. Typically, the first electrode 20 is operatively connected to the silicone layer 16. By “operatively connected”, it is meant that the first electrode 20 is connected to the silicone layer 16 through either a chemical or physical connection. The first electrode 20 may be formed by conventional methods that are known in the art. For example, the first electrode 20 may be formed through a high density plasma ion plating method. This method has the advantages of fast deposition rates, low growth temperatures, in-plane uniformity, reduced ion damage, and scale-up capability, to name a few. A typical thickness of the first electrode 20 is about 100 nm. Typically, the resistivity of the first electrode 20 is below 100 ohm/cm², more typically below 100 ohm/cm², and most typically below 40 ohm/cm². Typically, the first electrode 20 also has high transparency. Additionally, an insulating layer (not shown) may be formed on the first electrode 20. The insulating layer (not shown) may be formed from known insulating materials, such as silicon monoxide, through methods that are known in the art.

As shown in FIG. 2, the composite article 10 also typically includes a hole-injecting layer 22 disposed between the first electrode 20 and the cation-sensitive layer 14, especially when the composite article 10 is the OLED. The hole-injecting layer 22 may be formed from known hole-injecting materials, and may be formed through known processes.

Referring again to FIG. 2, the composite article 10 may further comprise a second electrode 24. The second electrode 24 may be disposed adjacent to the cation-sensitive layer 14, on an opposite side of the cation-sensitive layer 14 from the silicone layer 16. Like the first electrode 20, the second electrode 24 may be may be formed from any material known in the art as being suitable for electrodes, such as metals, metal oxides, and combinations thereof. While the second electrode 24 may also be formed from a transparent metal oxide, the type of material used for the second electrode 24 may depend, in part, on the configuration of the composite article 10 and the intended use of the composite article 10. For example, when the composite article 10 is the OLED, the substrate 12 comprises glass, and the first electrode 20 is formed from the transparent metal oxide, the second electrode 24 may be formed from any type of material that is suitable for an electrode, whether transparent or not. Alternatively, when the composite article 10 is the OLED, the substrate 12 comprises metal, and/or the first electrode 20 comprises a non-transparent metal oxide, then the second electrode 24 preferably comprises the transparent metal oxide.

The composite article 10 may further include a barrier layer 26 disposed adjacent to the cation-sensitive layer 14 on an opposite side of the cation-sensitive layer from the silicone layer 16. More specifically, referring to FIG. 2, the barrier layer 26 is typically disposed adjacent to the second electrode 24, on an opposite side of the second electrode 24 from the cation-sensitive layer 14. The barrier layer 26 may be formed from the same types of materials that are suitable for the substrate 12, and may have the same thickness as the substrate 12. However, it is to be appreciated that the barrier layer 26 may be formed from different materials than those used for the substrate 12, and may have a different thickness from the thickness of the substrate 12. Regardless, the barrier layer 26 is preferably formed from an excellent barrier material, such as steel, aluminum, or glass. Further, a second silicone layer (not shown) may be disposed between the barrier layer 26 and the second electrode 24; however, the second silicone layer is optional and depends upon the material used for the barrier layer 26. For example, if the barrier layer 26 is formed from a material that has no to low levels of cations, the second silicone layer may not be necessary. Alternatively, when the barrier layer 26 is formed from the same material used for the substrate 12, the second silicone layer may be preferred.

When the composite article 10 of the present invention is the OLED, a significant advantage of the cured silicone compositions described above is that they can improve the strength of the substrate 12 and, also that silicone layers 16 that include the cured silicone compositions function as an electrically insulating layer. These properties are very useful for the construction of bendable/flexible OLEDs on very thin glass substrates 12, such as those mentioned above that have a thickness less than 100 micrometers. These glass substrates 12 are extremely fragile and very difficult to handle. Due to the low thickness of the thin substrates 12, the thin substrates 12 are flexible and bendable and offer the possibilities to be an ideal substrate 12 for flexible/bendable OLEDs. When glass is used as the substrate 12, it protects the cation-sensitive layer, i.e., the organic light-emitting material, from vapor, oxygen, and moisture, and further protects the electrodes 20, 24. The shelf life of OLEDs that are built on glass substrates 12 with glass or metal barrier layers 26 is acceptably long. Conventional materials may be used to seal the edges of the OLEDs.

A measure of increase in strength of the substrate 12 can be indicated by the increase of bend radius when the substrate 12 including the silicone layer 16 is compared with the substrate 12 alone. For example, the Microsheet® is typically able to wrap around a 1.67 inch diameter cylinder without cracking, while Microsheet® including the silicone layer 16 disposed thereon is typically able to wrap around a 1 inch diameter cylinder without cracking.

The construction of the OLED typically continues with the deposition of the first electrode 20, which may be the transparent conductive anode, typically ITO. The anode formed from ITO has good resistivity and transparency. The cured silicone composition typically replicates the smooth surface of the substrate 12 and allows the first electrode 20, after deposition and crystallization, to retain a very smooth surface. A smooth surface of the first electrode is preferred prior to the subsequent steps of forming the hole-injecting layer 22 and organic light-emitting layer 14 thereon to ensure proper operation of the OLED. Thus, the silicone composition offers benefits in (a) improving strength of thin glass, (b) preventing cation diffusion to the electronic components of the device, and (c) maintaining the glass substrate smooth surface for the follow up layers.

The OLED can be completed by the addition of the barrier layer 26, which may be another thin glass layer, with the second silicone layer including the cured silicone composition disposed between the barrier layer 26 and the second electrode 24. The barrier layer 26 helps sandwich the active components of the OLED. The resulting OLED may be as thin as 150 micrometers. In another embodiment, the barrier layer 26 may be a thin layer of stainless steel to create a top-emitting OLED that is even thinner than when the barrier layer 26 includes another thin glass layer. Some of the stainless steel foils, including the thin layer of stainless steel and the second silicone layer, are as thin as 25 micrometers. For example, the OLED may then be about 100 micrometers thick (0.1 mm). The barrier layer 26 including the thin layer of stainless steel and the second silicone layer may provide electrical insulation and planarization of the stainless steel. The barrier layer 26 including thin layer of stainless steel and the second silicone layer offers additional protection to the substrate 12 formed from glass, while allowing the OLED to remain bendable and flexible.

The use of either steel or glass in the barrier layer 26 also offers production benefits. For example, a continuous or semicontinuous process for may be used to form the barrier layer 26 including the thin layer of stainless steel or the other thin layer of glass. When glass is used in the barrier layer 26, the barrier layer 26 may be formed as the glass floats while being cooled (or as the glass comes down from drawing towers), and the silicone composition can be applied to the glass when the appropriate cure temperature has been reached. The silicone compositions cure at high temperatures (often higher than 200° C.), which will be at the tail end of the cooling of the thin glass. As set forth above, the fiber reinforcement may be included in the silicone composition, especially in the silicone composition that is used to make the second silicone layer. Such a construction may improve the mechanical robustness of the glass in the barrier layer 26. Preferably, appropriate steps are taken to match refractive indices of reinforcing fibers included in the fiber reinforcement and the silicone composition. However, in some instances, a slight reduction in transparency may not be detrimental, such as for OLED-based lighting applications, rather than OLED-based display applications.

The following examples are meant to illustrate the invention and are not to be viewed in any way as limiting to the scope of the invention.

### Examples

Substrates were prepared including a silicone layer. Composite articles were also prepared in accordance with the present invention; however, the most relevant experimental results pertain to the substrate and the silicone layer and, more precisely, to the ability of the silicone layer to prevent cations from the substrate from migrating therethrough. As such, experimental results pertaining to numerous samples of substrates including silicone layers are first presented, followed by actual examples of composite articles that were prepared.

Numerous different types of substrates were used, as were numerous different types of silicone compositions. Details with respect to the types of materials and processing conditions for each substrate and silicone composition are set forth in the following individual examples.

### Example 1

A soda-lime glass substrate having a diameter of about 3 inches and a thickness of about 0.028 inches, with a transparent finish, 60/40-80/50 scratch/dig, and profile of flat to 2-3 waves/inch, was obtained from Valley Design Corporation of Shirley, Mass. The soda-lime glass substrate was cleaned by applying isopropanol and hand wiping the substrate, then acetone was spun on the substrate for 30 seconds at 1000 rpm. A silicone composition was pipetted onto the substrate, and then spun at 1000 rpm for 30 seconds. The silicone composition of this example was prepared using Resin A, which includes a siloxane of the following structure:

(MeSiO_{3/2})ₙ

wherein n is from 10 to 50, more specifically about 30. Resin A was obtained from SDC Corporation of Garden Grove, Calif. Resin A further includes colloidal silica present in an amount of about 20 percent by weight based on the total weight of the silicone composition. Resin A is the siloxane composition for purposes of this example.

Prior to curing the silicone composition on the substrate, the coated substrate was broken into several pieces, and the silicone composition on the pieces was cured under different conditions. To cure the silicone compositions on the substrates, the coated substrates were placed in a Fisher Isotemp forced air oven using a ramp rate of 1.7° C./min. Annealing in air was done in a Fisher Isotemp Programmable Forced-Draft furnace. Annealing in nitrogen was done in a Lindburg furnace after 4 cycles of pulling vacuum/back purging with high purity N₂. Four different samples were prepared as set forth below:
a. Cured in the forced air oven at 100° C. for 2 hours in air.
b. Cured in the forced air oven at 200° C. for 2 hours in air.
c. Cured in the forced air furnace at 350° C. for 2 hours in air.
d. Cured in the forced air furnace at 500° C. for 2 hours in air.

### Example 2

A substrate was obtained and prepared as set forth in Example 1. The substrate was coated with a silicone composition in the same manner as in Example 1, except a different silicone composition was used. To prepare the silicone composition, Resin B was used, which includes a siloxane of the formula:

(MeSiO_{3/2})_{0.45}(PhSiO_{3/2})_{0.4}(Ph₂SiO)_{0.1}(PhMeSiO)_{0.05}

3.98 g of Resin B were mixed with 12.02 g toluene to produce a 24.9% siloxane solution. 3.2634 g of the siloxane solution was mixed with 0.0187 g of Y-177 catalyst commercially available from Dow Corning Corporation of Midland, Mich. to form the silicone composition. The silicone composition was filtered through a 0.2 μm, then a 0.1 μm Whatman filter. The filtered silicone composition was applied to the glass substrate and spun as described above. For Example 2a, the silicone composition was cured on the substrate in the forced air oven at 100° C. for 1 hour, then at 160° C. for 1 hour, and then at 200° C. for 1 hour. For Example 2b, the silicone composition was additionally heat aged at 300° C. for 1 hour in nitrogen.

### Example 3

A substrate was obtained and prepared as set forth in Example 1. The substrate was coated with a silicone composition in the same manner as in Example 1, except a different silicone composition was used. To prepare the silicone composition, Resin C was used, which includes a siloxane of the formula:

(MeSiO_{3/2})ₙ

wherein n is from 10 to 50, more specifically about 30. A 29.5 wt % solution of Resin C in MIBK was prepared and centrifuged for 15 min, then filtered through a 0.2 μm filter to form the silicone composition. The filtered silicone composition was applied to the substrate and spun as described above. For Example 3a, the silicone composition on the substrate was cured in the forced air oven at 100° C. for 1 hour, then at 160° C. for 1 hour, and then at 200° C. for 1 hour. For Example 3b, the coated glass substrate was additionally heat aged at 300° C. for 1 hour in nitrogen.

### Example 4

A substrate was obtained and prepared as set forth in Example 1. The substrate was coated with a silicone composition in the same manner as in Example 1, except a different silicone composition was used. To prepare the silicone composition, Resin D was used, which includes a siloxane of the formula:

(PhSiO_{3/2})_{0.75}(Me₂ViSiO_{1/2})_{0.25}

A 25 wt % solution of Resin D in MIBK was prepared by mixing 5.02 g of Resin D with 15.03 g of MIBK. 3.4991 g of the solution were mixed with 0.0230 g of a catalyst comprising 1000 ppm of platinum in toluene with 4 molar excess of Ph₃P. The solution was filtered through a 0.2 μm filter, then a 0.1 μm filter, to form the silicone composition. The filtered silicone composition was applied to the substrate and spun as described above. For Example 4a, the silicone composition on the substrate was cured in the forced air oven at 100° C. for 1 hour, then at 160° C. for 1 hour, and then at 200° C. for 1 hour. For Example 4b, the coated glass substrate was additionally heat aged at 300° C. for 1 hour in nitrogen.

### Example 5

A substrate was obtained and prepared as set forth in Example 1. The substrate was coated with a silicone composition in the same manner as in Example 1, except a different silicone composition was used. To prepare the silicone composition, Resin E was used, which includes a siloxane of the formula:

(Me₂ViSiO_{1/2})_{0.15}(PhSiO_{3/2})_{0.75}(SiO_{4/2})_{0.1}

A 25 wt % solution of Resin E in toluene was prepared by mixing 8.74 g of Resin E with 26.24 g of toluene. 3.6253 g of the solution were mixed with 0.0184 g of a catalyst comprising 1000 ppm of platinum in toluene with 4 molar excess of Ph₃P. The solution was filtered through a 0.2 μm filter, then a 0.1 μm filter, to form the silicone composition. The filtered silicone composition was applied to the substrate and spun as described above. For Example 5a, the silicone composition on the substrate was cured in the forced air oven at 100° C. for 1 hour, then at 160° C. for 1 hour, and then at 200° C. for 1 hour. For Example 5b, the coated glass substrate was heat aged additionally at 300° C. for 1 hour in nitrogen.

### Example 6

A borofloat glass substrate having a diameter of about 3 inches and a thickness of about 0.028 inches, with a transparent finish, 60/40-80/50 scratch/dig, and profile of flat to 2-3 waves/inch, was obtained from Valley Design Corporation of Shirley, Mass. The substrate was cleaned by applying isopropanol and hand wiping the substrate, then acetone was spun on the substrate for 30 seconds at 1000 rpm. The silicone composition of Example 1 was pipetted onto the substrate, and then spun at 1000 rpm for 30 seconds.

For Example 6a, the silicone composition on the substrate was cured in the forced air oven at 100° C. for 1 hour, then at 160° C. for 1 hour, and then at 200° C. for 1 hour. For Example 6b, the coated glass substrate was additionally heat aged at 500° C. for 1 hour in nitrogen.

### Example 7

A 4 inch×4 inch Microsheet® glass substrate was obtained from Corning, Incorporated of Corning, N.Y. The substrate was coated with a silicone composition in the same manner as in Example 4, with the same silicone composition as was used in Example 4. Specifically, a 25 wt % solution of Resin D in MIBK was prepared by mixing 5.02 g of Resin D with 15.03 g of MIBK. 4.5454 g of the solution were mixed with 0.0145 g of a catalyst comprising 1000 ppm of platinum in toluene with 4 molar excess of Ph₃P. The solution was filtered through a 0.2 μm filter, then a 0.1 μm filter, to form the silicone composition. The filtered silicone composition was applied to the substrate and spun as described above. For Example 7a, the silicone composition on the substrate was cured in the forced air oven at 100° C. for 1 hour, then at 160° C. for 1 hour, and then at 200° C. for 1 hour. For Example 7b, the coated glass substrate was additionally heat aged at 300° C. for 1 hour in nitrogen.

### Example 8

A 4 inch×4 inch Microsheet® glass substrate was coated with a silicone composition as in Example 1, with a silicone composition including Resin A. However, the silicone composition was prepared by mixing 8.75 g of Resin A and 8.76 g of isopropanol. The silicone composition was applied to the substrate and spun as described above. For Example 8a, the silicone composition on the substrate was cured in the forced air oven at 100° C. for 1 hour, then at 160° C. for 1 hour, and then at 200° C. for 1 hour. For Example 8b, the coated glass substrate was additionally heat aged at 300° C. for 1 hour in nitrogen.

### Example 9

A 4 inch×4 inch Microsheet® glass substrate was obtained from Corning, Incorporated of Corning, N.Y. The substrate was coated with a silicone composition prepared from Resin E as set forth above in Example 5. Specifically, a 19.9 wt % solution of Resin E in toluene was prepared by mixing 5.43 g of Resin E with 21.86 g of toluene. 4.5208 g of the solution were mixed with 0.0132 g of a catalyst comprising 1000 ppm of platinum in toluene with 4 molar excess of Ph₃P. The solution was filtered through a 0.2 μm filter, then a 0.1 μm filter, to form the silicone composition. The filtered silicone composition was applied to the substrate and spun as described above. For Example 9a, the silicone composition on the substrate was cured in the forced air oven at 100° C. for 1 hour, then at 160° C. for 1 hour, and then at 200° C. for 1 hour. For Example 9b, the coated glass substrate was additionally heat aged at 300° C. for 1 hour in nitrogen.

### Example 10

A 4 inch×4 inch Microsheet® glass substrate was obtained from Corning, Incorporated of Corning, N.Y. The substrate was coated with a silicone composition prepared from Resin C as set forth above in Example 3. Specifically, a 29.5 wt % solution of Resin C in MIBK was prepared, and the solution was filtered through a 0.45 μm filter to form the silicone composition. About 1 ml of the filtered silicone composition was applied to the substrate and spin coated at 1500 rpm for 30 seconds. For Example 10a, the silicone composition on the substrate was cured in the forced air oven at 200° C. for 3 hours. For Example 10b, the coated glass substrate was additionally heat aged at 300° C. for 1 hour in nitrogen.

### Comparative Examples

Substrates were also prepared without a silicone layer for comparative purposes. Comparative Example 1 is an uncoated soda lime glass substrate, used as received. Comparative Example 2 is an uncoated soda lime glass substrate heat aged at 500° C. for 2 hours in air. Comparative Example 3 is an uncoated soda lime glass substrate heat aged at 300° C. for 1 hour in nitrogen. Comparative Example 4 is uncoated Borofloat glass substrate, used as received. Comparative Example 5 is uncoated Borofloat glass substrate heat aged at 500° C. for 2 hours in air. Comparative Example 6 is uncoated Microsheet®, used as received. Comparative Example 7 is uncoated Microsheet®, heat aged in the forced air furnace at 500° C. for 2 hours in air. Comparative Example 7 is uncoated Microsheet®, heat aged in the forced air furnace at 300° C. for 1 hour in air. Comparative Example 8 is uncoated Microsheet®, heat aged in the forced air furnace at 300° C. for 1 hour in nitrogen.

### Test Methods

Secondary-ion mass spectrometry (SIMS) was performed on Examples 1c, 2a, 4a, and 5a, as well as on Comparative Example 1, the results of which are shown in FIG. 3 for the presence of sodium cations. SIMS was also performed on Examples 1d, 2b, 4b, and 5b, the results of which are shown in FIG. 4 for the presence of sodium cations. The SIMS technique is very sensitive to mobile cations, down to the ppm level. SIMS is also capable of depth profiling for ions through the barrier layer to a depth of up to about 3 μm. SIMS analysis was completed by Evans Analytical Group of East Windsor, N.J., using a Quadrupole MS instrument. Table 1 highlights the conditions used.

TABLE 1

| | |
|---|---|
| Instrument | Quadrupole MS |
| Elements Monitored | C, O, Na, Si, K, Ca |
| Primary Ion Beam | Cs |
| Secondary Ion Polarity | Negative |
| Incident Angle | 60° |
| Oxygen Leak | No |
| Charge Neutralization | Yes |
| Surface Conductive Coating | None |
| Liquid Nitrogen Cold Trap | No |

The sodium and potassium were quantified by running concurrent analysis of EAG standard “110,” while approximate quantification of the calcium was done. The carbon, oxygen, and silicon were not quantified. The detection limits for this analysis was 1×10¹⁷ atoms/cm³ for sodium, potassium, and calcium.

X-ray photoelectron spectroscopy (XPS), also known as electron spectroscopy for chemical analysis (ESCA) was also performed for each Example as well as for each Comparative Example. This technique can detect the concentration of ions at about 0.1 atomic weight percent levels. ESCA analysis was done using a Kratos Analytical AXIS 165 ESCA using a monochromatic Al Ka x-ray source operating at 120 W. A low energy electron flood was used for surface charge compensation. Each Example and Comparative Example was analyzed in 3 spots. A low resolution survey spectrum and high-resolution oxygen 1s, carbon 1s, and silicon 2p spectra were obtained at each analysis position. The area of analysis was roughly 0.8 mm×1.4 mm. The surface compositions are given in atomic weight percent. Repeatability was estimated to be 0.5 atomic weight percent. Table 2, below, presents the ESCA data for Examples 1-6, as well as for Comparative Examples 1-5, with the values presented under the various atomic designations representing atomic weight percentage as a percentage of the total atomic weight of all atoms on the surface of the Example tested.

TABLE 2

| | Thickness | | | | | | | | | | | | | |
|---|---|---|---|---|---|---|---|---|---|---|---|---|---|---|
| Example | (μm) | Na | O | C | Si | Sn | Ca | K | S | Mg | Al | Cl | B | N |
| Comp. | n/a | 3.4 | 45.2 | 31 | 17 | 0.1 | 1 | 0.2 | 0.3 | 0.8 | 1.2 | 0 | 0 | n/a |
| Ex. 1 | | | | | | | | | | | | | | |
| Comp. | n/a | 8.7 | 58.3 | 6 | 22.1 | 0.1 | 1.4 | 0.2 | 0.1 | 1.1 | 1.4 | 0.4 | 0.3 | n/a |
| Ex. 2 | | | | | | | | | | | | | | |
| Comp. | n/a | 6.9 | 46.8 | 27.5 | 12.3 | 2.7 | 1.4 | 0.1 | 0.7 | 0.8 | 0.5 | 0.1 | n/a | 0.2 |
| Ex. 3 | | | | | | | | | | | | | | |
| Comp. | n/a | 0.4 | 50 | 24.4 | 17.7 | 2.2 | 0.3 | 0.2 | 0.5 | n/a | 0.7 | n/a | 2.3 | 1.2 |
| Ex. 4 | | | | | | | | | | | | | | |
| Comp. | n/a | 6.7 | 58.2 | 7.1 | 20.8 | 2.4 | 0.4 | 0.3 | 0.3 | 0.2 | 0.7 | n/a | 2.7 | 0.2 |
| Ex. 5 | | | | | | | | | | | | | | |
| Comp. | n/a | 3.5 | 50.6 | 21.1 | 17 | n/a | n/a | 2.2 | n/a | n/a | n/a | n/a | n/a | n/a |
| Ex. 6 | | | | | | | | | | | | | | |
| Comp. | n/a | 3.4 | 60.3 | 6.8 | 20.3 | n/a | n/a | 2.5 | n/a | n/a | n/a | n/a | n/a | n/a |
| Ex. 7 | | | | | | | | | | | | | | |
| Comp. | n/a | 3.1 | 60.1 | 7.9 | 19.7 | n/a | n/a | 2.3 | n/a | n/a | n/a | n/a | n/a | n/a |
| Ex. 8 | | | | | | | | | | | | | | |
| Comp. | n/a | 3.9 | 55.4 | 13.2 | 18.7 | n/a | n/a | 2.4 | n/a | n/a | n/a | n/a | n/a | n/a |
| Ex. 9 | | | | | | | | | | | | | | |
| Ex. 1a | 3.76 | 0 | 43.1 | 31.7 | 25.3 | n/a | n/a | n/a | n/a | n/a | n/a | n/a | n/a | n/a |
| Ex. 1b | 3.18 | 0 | 42.9 | 31.5 | 25.6 | n/a | n/a | n/a | n/a | n/a | n/a | n/a | n/a | n/a |
| Ex. 1c | 3.12 | 0 | 41.4 | 33.3 | 25.3 | n/a | n/a | n/a | n/a | n/a | n/a | n/a | n/a | n/a |
| Ex. 1d | 2.71 | 0 | 57.5 | 15.7 | 26.8 | n/a | n/a | n/a | n/a | n/a | n/a | n/a | n/a | n/a |
| Ex. 2a | 1.78 | 0.02 | 22.6 | 63.7 | 13.7 | n/a | n/a | n/a | n/a | n/a | n/a | n/a | n/a | n/a |
| Ex. 2b | n/a | 0 | 22.6 | 63.9 | 13.5 | n/a | n/a | n/a | n/a | n/a | n/a | n/a | n/a | n/a |
| Ex. 3a | 2.1 | 0 | 43.3 | 31.4 | 25.3 | n/a | n/a | n/a | n/a | n/a | n/a | n/a | n/a | n/a |
| Ex. 3b | n/a | 0 | 61.4 | 11.8 | 26.7 | n/a | n/a | n/a | n/a | n/a | n/a | n/a | n/a | 0.1 |
| Ex. 4a | 0.96 | 0 | 19.3 | 68.2 | 12.4 | n/a | n/a | n/a | n/a | n/a | n/a | n/a | n/a | n/a |
| Ex. 4b | n/a | 0 | 19.2 | 68.7 | 12.2 | n/a | n/a | n/a | n/a | n/a | n/a | n/a | n/a | n/a |
| Ex. 5a | 1.48 | 0 | 20.5 | 67.1 | 12.4 | n/a | n/a | n/a | n/a | n/a | n/a | n/a | n/a | n/a |
| Ex. 5b | n/a | 0 | 20.3 | 67.3 | 12.4 | n/a | n/a | n/a | n/a | n/a | n/a | n/a | n/a | n/a |
| Ex. 6a | 3.55 | 0 | 43.3 | 31.6 | 25.1 | n/a | n/a | n/a | n/a | n/a | n/a | n/a | n/a | n/a |
| Ex. 6b | n/a | 0.1 | 54.1 | 19.9 | 26 | n/a | n/a | n/a | n/a | n/a | n/a | n/a | n/a | n/a |
| Ex. 7a | 1 | 0 | 21.2 | 63.5 | 15.2 | n/a | n/a | n/a | n/a | n/a | n/a | n/a | n/a | n/a |
| Ex. 7b | 1 | 0 | 21.3 | 63.6 | 15.2 | n/a | n/a | n/a | n/a | n/a | n/a | n/a | n/a | n/a |
| Ex. 8a | 1.1 | 0 | 43.4 | 31.4 | 25.3 | n/a | n/a | n/a | n/a | n/a | n/a | n/a | n/a | n/a |
| Ex. 8b | 1.1 | 0 | 43.2 | 31.6 | 25.2 | n/a | n/a | n/a | n/a | n/a | n/a | n/a | n/a | n/a |
| Ex. 9a | 1 | 0 | 22.2 | 61.3 | 16.5 | n/a | n/a | n/a | n/a | n/a | n/a | n/a | n/a | n/a |
| Ex. 9b | 1 | 0 | 22.3 | 61.1 | 16.6 | n/a | n/a | n/a | n/a | n/a | n/a | n/a | n/a | n/a |
| Ex. 10a | 1.4 | 0 | 39.7 | 35.2 | 25.1 | n/a | n/a | n/a | n/a | n/a | n/a | n/a | n/a | n/a |
| Ex. 10b | 1.4 | 0 | 40 | 35.1 | 24.9 | n/a | n/a | n/a | n/a | n/a | n/a | n/a | n/a | n/a |

### Results

Based on the results presented in FIGS. 3 and 4, as well as in Table 2 above, it is clear that less cations are present on or near the surface of the Examples made in accordance with the present invention, as compared to the Comparative Examples. More specifically, XPS and ESCA results showed that when silicone compositions were used, the cation detection was below the limit of the instrument (less than 0.1 atomic percent). The SIMS data corroborated the XPS and ESCA results by showing cation reduction of from 2 to 4 orders of magnitude over the bare glass substrate (refer to FIGS. 3 and 4). Thus, it is clear that the silicone layer includes less cations on or near the surface thereof than the substrates upon which the silicone layers are disposed. Further, it is clear that some silicone compositions have less cations on or near the surface of silicone layers formed therefrom as compared to silicone layers formed from other silicone compositions. For example, as shown in FIG. 4, the silicone composition used in Example 4b exhibits lower SIMS values for the presence of sodium cations on or near the surface of the silicone layer formed from that silicone composition after annealing at a temperature of about 300° C. for a period of about 60 minutes in N₂ atmosphere. Variable thicknesses of the different silicone layers on the substrate are responsible for variable onset points where cation concentration rises.

### Example 11

An OLED is prepared in accordance with the present invention on Microsheet® glass substrates. A hole injection material (HIM), and organic light-emitting polymer (LEP) Red H2 commercially available from Sumation of Tokyo, JP, are first prepared in electronic grade solvents supplied by ACROS Organics of Geel, Belgium. More specifically, 2.0 wt % of the HIM is prepared in methyl isobutyl ketone, and 1.5 wt % of the LEP is prepared in xylene. The HIM was doped with a titanium cure promoter, Ti(PrO)₄ commercially available from Sigma-Aldrich Corporation of St. Louis, Mo., to a concentration equivalent to 0.2 wt %. The LEP was mixed on a wrist action shaker for at least 2 hours before use to insure adequate dissolution.

A silicone layer was formed on the Microsheet® glass substrates. The silicone layer is formed from a silicone composition of the hydrosilation type, which is made with a crosslinking agent and a hydrosilation catalyst. The resin composition is (Me₂ViSiO_{1/2})_{0.15}(PhSiO_{3/2})_{0.75}(SiO_{4/2})_{0.10}. A first electrode layer comprising ITO was deposited onto the silicone layer. The ITO was deposited via a high energy plasma ion plating method. It was determined that the thickness of the ITO was 100 nm and the resistance was 35 ohm/cm².

The substrates including the silicone layer and the first electrode were cleaned by spin-casting p.a. grade isopropyl alcohol (IPA) from ACROS Organic on a Chemat KW-4A spin-coater at 2000 rpm for 20 sec with about 750 rpm acceleration. The IPA was filtered with a 0.1 um Teflon Whatman Puradisc syringe filter immediately before use.

Next, an insulating layer (not shown) was formed on the first electrode by depositing 100 nm of 99.99% pure silicon monoxide (SiO), commercially available from Sigma-Aldrich Corporation, under vacuum at 2.0×10⁻⁶ mbar using a mask. This was accomplished in a BOC Edwards Auto 306A Evaporator by heating the SiO in a molybdenum boat under vacuum.

The substrates were conditioned by exposing the surface of the first electrode to an oxygen plasma for 5 minutes immediately before spin casting the HIM onto the first electrode. Spin casting of the HIM was completed in an ISO Class 6 clean room on the Chemat spin coater by using a plain glass slide as a backer for the substrate. The substrate was adhered to the glass backer by means of a small drop of water placed on the backer. The HIM was pre-filtered with a 0.1 um Teflon Whatman Puradisc syringe filter and spun at 2000 rpm for 30 sec with about 750 rpm acceleration. The HIM was cured in a Fisher Isotemp Oven in air that was set to 40° C. and increased to 190° C. in 5° C. increments every 5 minutes. Once 190° C. was reached, the temperature was held for 5 minutes, then reduced to 100° C. before removing the substrates from the oven. The cooling process took approximately 20 minutes. As cured, the HIM layer was expected to be about 45-50 nm thick.

The solutions of the LEPs were spin-cast in a similar fashion as the HIM with only a few differences. The solutions of the LEPs were pre-filtered with a 0.2 um polypropylene Whatman Puradisc syringe filter and spun at 2250 rpm for 40 sec with about 750 rpm acceleration, and the resulting LEP layers were annealed in the Fisher oven at 100° C. for 30 minutes in air. All other aspects were the same as preparation of the HIM layer. Under these conditions, the LEP layers were expected to be about 50-70 nm thick.

All composite articles including the HIM layer and the LEP layer were transferred to an MBraun dry glove box to deposit the second electrode, i.e., the cathode, and to seal the composite articles. A barium/aluminum cathode was deposited in a BOC Edwards Auto 500 Vacuum evaporator on top of the LEP layer of each article. Under a vacuum of 2.0×10⁻⁶ mbar, 10 nm of barium was evaporated from a tungsten boat. Immediately following the barium, 150 nm of aluminum was evaporated from a coiled, alumina coated, tungsten filament. The articles were allowed to outgas for 30 min at vacuum before the deposition took place.

Example 1 la was sealed with a barrier layer formed from another sheet of Microsheet® glass, with a second silicone layer disposed between the glass and the second electrode. The second silicone layer was formed from the same silicone composition used above. Example 11b was sealed with a stainless steel barrier layer, also with a second silicone layer disposed between the steel and the second electrode. The barrier layers were formed by applying 3 drops of ELC-2500 Clear epoxy, from Electro-Lite Corporation, at the top of the cathode bars and placing either the stainless steel or glass, coated with the second silicone layer, on top of cathode. The epoxy was cured under a 365 nm UV lamp for 15 minutes. Care was taken to insure part of the cathode was still exposed so an electrical contact could be made. A photograph of an OLED prepared according to the aforementioned process is shown in FIG. 5. The total thickness of Example 11a was about 150 micron; the total thickness of Example 11b was about 100 micron. Both Example 11a and 11b were tested periodically to determine if they were functional over a period of time or if they deteriorated. Both examples remained functional in excess of 40 days (for Example 11a), and 9 months (for Example 11b).

Obviously, many modifications and variations of the present invention are possible in light of the above teachings. The invention may be practiced otherwise than as specifically described within the scope of the appended claims. In addition, the reference numerals are merely for convenience and are not to be read in any way as limiting.

What is claimed is:

1. A composite article comprising:
a substrate comprising cations on a surface thereof in an amount of at least 0.1 atomic weight percent based on the total atomic weight of the atoms on said surface of said substrate;
a cation-sensitive layer comprising a cation-sensitive material and disposed on said surface of said substrate; and
a silicone layer disposed between said substrate and said cation-sensitive layer and comprising a cured silicone composition for preventing cations from migrating from said substrate to said cation-sensitive layer, wherein said cured silicone composition is selected from the group of hydrosilation-cured silicone compositions, condensation-cured silicone compositions, and free radical-cured silicone compositions.

2. (canceled)

3. A composite article as set forth in claim 1 wherein said cured silicone composition is a hydrosilylation-cured silicone composition and wherein said hydrosilylation-cured silicone composition comprises the reaction product of:
(A) a silicone resin; and
(B) an organosilicon compound having an average of at least two silicon-bonded hydrogen atoms per molecule in an amount sufficient to cure said silicone resin;
in the presence of (C) a catalytic amount of a hydrosilylation catalyst.

4. A composite article as set forth in claim 3 wherein said silicone resin (A) has the formula:
(R¹R²₂SiO_{1/2})_{w}(R²₂SiO_{2/2})ₓ(R²SiO_{3/2})_{y}(SiO_{4/2})_{z}
wherein R¹ is a C₁ to C₁₀ hydrocarbyl group or a C₁ to C₁₀ halogen-substituted hydrocarbyl group, both free of aliphatic unsaturation, R² is R¹ or an alkenyl group, w is from 0 to 0.9, x is from 0 to 0.9, y is from 0 to 0.99, z is from 0 to 0.85, w+x+y+z=1, y+z/(w+x+y+z) is from 0.1 to 0.99, and w+x/(w+x+y+z) is from 0.01 to 0.9, provided said silicone resin has an average of at least two silicon-bonded alkenyl groups per molecule.

5. (canceled)

6. A composite article as set forth in claim 1 wherein said cured silicone composition is a condensation-cured silicone composition and wherein said condensation-cured silicone composition comprises the reaction product of:
(A″) a silicone resin having at least two of a silicon-bonded hydroxy group or a hydrolysable group; and
optionally, (B′) a cross-linking agent having silicon-bonded hydrolysable groups,
optionally, in the presence of (C′) a catalytic amount of a condensation catalyst.

7. A composite article as set forth in claim 6 wherein said silicone resin (A″) has the formula:
(R¹R⁶₂SiO_{1/2})_{w′}(R⁶₂SiO_{2/2})_{x′}(R⁶SiO_{3/2})_{y′}(SiO_{4/2})_{z′}
wherein R¹ is a C₁ to C₁₀ hydrocarbyl group or a C₁ to C₁₀ halogen-substituted hydrocarbyl group, both free of aliphatic unsaturation, R⁶ is R¹, —H, —OH, or a hydrolysable group, w′ is from 0 to 0.8, x′ is from 0 to 0.95, y′ is from 0 to 1, z′ is from 0 to 0.99, w′+x′+y′+z′=1, and wherein said silicone resin (A″) has an average of at least two silicon-bonded hydrogen atoms, hydroxy groups, or hydrolysable groups per molecule.

8. A composite article as set forth in claim 7 wherein said silicone composition further includes an inorganic filler in particulate form.

9. (canceled)

10. A composite article as set forth in claim 1 wherein said cured silicone composition is a free radical-cured silicone composition and wherein said free radical-cured silicone composition is formed from a silicone resin having the formula:
(R¹R⁹₂SiO_{1/2})_{w″}(R⁹₂SiO_{2/2})_{x″}(R⁹SiO_{3/2})_{y″}(SiO_{4/2})_{z″},
wherein R¹ is a C₁ to C₁₀ hydrocarbyl group or a C₁ to C₁₀ halogen-substituted hydrocarbyl group, both free of aliphatic unsaturation; R⁹ is R¹, alkenyl, or alkynyl; w″ is from 0 to 0.99; x″ is from 0 to 0.99; y″ is from 0 to 0.99; z″ is from 0 to 0.85; and w″+x″+y″+z″=1.

11. A composite article as set forth in claim 1 wherein said silicone composition includes at least one functional group prior to curing for adhering said cured silicone composition to said substrate.

12. A composite article as set forth in claim 11 wherein said at least one functional group is selected from the group of silanol groups, alkoxy groups, epoxy groups, silicon hydride groups, acetoxy groups, and combinations thereof.

13. A composite article as set forth in claim 1 further comprising an adhesive layer disposed between said silicone layer and said substrate.

14. A composite article as set forth in claim 13 wherein said adhesive layer comprises a silicone-based adhesive.

15. A composite article as set forth in claim 1 wherein said silicone layer further comprises a fiber reinforcement.

16. A composite article as set forth in claim 1 wherein said silicone layer has a thickness of at least about 0.1 micron.

17. A composite article as set forth in claim 1 wherein said substrate comprises a material selected from the group of glass, metal, and combinations thereof.

18. A composite article as set forth in claim 17 wherein said substrate comprises glass and wherein said glass is selected from the group of soda-lime glass, borofloat glass, aluminasilicate glass, and combinations thereof.

19. A composite article as set forth in claim 1 wherein said substrate has a thickness of less than or equal to 0.5 mm.

20. A composite article as set forth in claim 1 wherein said cation-sensitive material is further defined as an organic light-emitting material.

21. A composite article as set forth in claim 1 further comprising a first electrode disposed between said cation-sensitive layer and said silicone layer.

22. A composite article as set forth in claim 21 wherein said first electrode is operatively connected to said silicone layer.

23. A composite article as set forth in claim 21 further comprising a hole-injecting layer disposed between said first electrode and said cation-sensitive layer.

24. A composite article as set forth in claim 1 further comprising a barrier layer disposed adjacent said cation-sensitive layer on an opposite side of said cation-sensitive layer from said silicone layer.

25. A composite article as set forth in claim 24 wherein said barrier layer comprises a material selected from the group of conventional vitreous materials, metals, and combinations thereof.

26. A composite article as set forth in claim 1 wherein said cured silicone composition has units represented by the formula (PhSiO_{3/2}).

27. A composite article as set forth in claim 4 wherein y is from 0.5 to 0.8.
